(19) United States
(12) Patent Application Publication
(10) Pub. No.: US 2026/0026158 A1
(43) Pub. Date: Jan. 22, 2026

(54) DISPLAY APPARATUS

(71) Applicant: LG Display Co., Ltd., Seoul (KR)

(72) Inventors: YoonSeong PARK, Daegu (KR); Hyunseok NA, Hwaseong-si (KR); Hyoungsun PARK, Seoul (KR)

(73) Assignee: LG Display Co., Ltd., Seoul (KR)

(21) Appl. No.: 19/221,095

(22) Filed: May 28, 2025

(30) Foreign Application Priority Data
Jul. 17, 2024 (KR) 10-2024-0094616

(51) Int. Cl. H10H 29/41; H10H 29/37; H10H 29/852

(52) U.S. Cl. CPC H10H 29/41; H10H 29/37; H10H 29/852

(57) ABSTRACT

A display apparatus is provided. The display apparatus includes a substrate, a plurality of pixel driving circuits on the substrate, a plurality of insulating layers on the plurality of pixel driving circuits, a plurality of banks on the plurality of insulating layers, a plurality of micro LEDs on the plurality of banks and electrically connected to each of the plurality of pixel driving circuits. A dam is disposed between adjacent pixel driving circuits and formed on the same layer as the plurality of pixel driving circuits. The dam is configured to control the flow of the insulating layers and enhance the structural stability of the display. Thus, a signal distortion of the plurality of signal lines disposed on the pixel driving circuit may be suppressed, thereby improving display performance and reliability.

### CROSS-REFERENCE TO RELATED APPLICATIONS

This application claims the priority of Korean Patent Application No. 10-2024-0094616 filed on Jul. 17, 2024, in the Korean Intellectual Property Office, the disclosure of which is incorporated herein by reference.

### BACKGROUND

### Technical Field

The present disclosure relates to a display apparatus.

### Description of the Related Art

A display apparatus is applied to various electronic apparatuses such as TV, mobile phones, laptops, and tablets.

The display apparatus includes an organic light emitting display (OLED) apparatus that emits light by itself, a liquid crystal display (LCD) apparatus that requires a separate light source, etc.

Recently, the display apparatus including a micro light emitting diode (micro LED) is attracting attention as a next-generation display apparatus. Since the light emitting diode is made of an inorganic material rather than an organic material, the micro light emitting diode may have a fast-lighting speed and excellent light emitting efficiency, and may display a high brightness image, compared to the liquid crystal display apparatus or the organic light emitting display apparatus.

### BRIEF SUMMARY

The present disclosure provides a display apparatus which planarizes an insulating layer between pixel driving circuits.

The present disclosure provides a display apparatus which suppresses a signal distortion of the plurality of signal lines disposed on the pixel driving circuit.

Technical benefits of the present disclosure are not limited to the above-mentioned benefits, and other benefits, which are not mentioned above, can be clearly understood by those skilled in the art from the following descriptions.

A display apparatus according to an exemplary embodiment of the present disclosure comprises a substrate, a plurality of pixel driving circuits disposed on the substrate, a plurality of insulating layers disposed on the plurality of pixel driving circuits, a plurality of banks disposed on the plurality of insulating layers, a plurality of micro LEDs which is disposed on the plurality of banks and is electrically connected to each of the plurality of pixel driving circuits, and a dam which is disposed on the same layer as the plurality of pixel driving circuits and is disposed between adjacent pixel driving circuits, among the plurality of pixel driving circuits.

A display apparatus according to another exemplary embodiment of the present disclosure comprises a substrate including an active area including a plurality of pixels and a non-active area, a structure which is disposed on the substrate and includes a plurality of openings, a plurality of pixel driving circuits which is disposed on the substrate and is disposed in each of the plurality of openings, a plurality of insulating layers disposed on the substrate, a plurality of banks disposed in the plurality of pixels on the plurality of insulating layers, a plurality of micro LEDs which is disposed on the plurality of banks and is electrically connected to each of the plurality of pixel driving circuits, and a plurality of first connection lines which is disposed so as to overlap the structure and connects the plurality of micro LEDs and the plurality of pixel driving circuits.

According to the present disclosure, a flow of an insulating layer which encloses a plurality of pixel driving circuits may be controlled.

According to the present disclosure, a curve of the plurality of signal lines may be minimized.

According to the present disclosure, the plurality of signal lines is formed to have a uniform thickness to suppress the luminance deviation.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is an exploded perspective view of a display apparatus according to an exemplary embodiment of the present disclosure;

FIG. 2 is a plan view of a display apparatus according to an exemplary embodiment of the present disclosure;

FIG. 3 is a plan view of a display apparatus according to an exemplary embodiment of the present disclosure;

FIG. 4 is an enlarged view of a display apparatus according to an exemplary embodiment of the present disclosure;

FIG. 5 is a view illustrating a circuit structure according to an exemplary embodiment of the present disclosure;

FIG. 6 is a plan view of a display apparatus according to an exemplary embodiment of the present disclosure;

FIG. 7 is a plan view of a display apparatus according to an exemplary embodiment of the present disclosure;

FIG. 8 is a plan view of a display apparatus according to an exemplary embodiment of the present disclosure;

FIG. 9A is a cross-sectional view taken along A-A′ of FIG. 3;

FIG. 9B is a cross-sectional view taken along B-B′ of FIG. 3;

FIG. 10 is a cross-sectional view taken along C-C′ of FIG. 4;

FIG. 11 is a cross-sectional view of a display apparatus according to an exemplary embodiment of the present disclosure;

FIGS. 12A to 12E are process diagrams for explaining a manufacturing method of a display apparatus according to an exemplary embodiment of the present disclosure;

FIG. 13 is a cross-sectional view of a display apparatus according to another exemplary embodiment of the present disclosure;

FIGS. 14A to 14H are process diagrams for explaining a manufacturing method of a display apparatus according to other exemplary embodiments of the present disclosure;

FIG. 15 is a cross-sectional view of a display apparatus according to still another exemplary embodiment of the present disclosure;

FIG. 16 is a plan view of a display apparatus according to still another exemplary embodiment of the present disclosure;

FIG. 17 is a cross-sectional view taken along D-D′ of FIG. 16;

FIG. 18 is a cross-sectional view of a display apparatus according to still another exemplary embodiment of the present disclosure;

FIG. 19 is a cross-sectional view of a display apparatus according to still another exemplary embodiment of the present disclosure; and

FIGS. 20 to 23 are views illustrating devices to which a display apparatus according to exemplary embodiments of the present disclosure is applied.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When the relation of a time sequential order is described using the terms such as “after,” “continuously to,” “next to,” and “before,” the order may not be continuous unless the terms are used with the term “immediately” or “directly.”

Although the terms first, second, or the like are used to describe various components, these components are not limited by these terms. These terms are only used to distinguish one component from another. Thus, a first component referred to below may also be a second component within the technical scope of the present disclosure.

In describing components of the present disclosure, terms such as first, second, A, B, (a), or (b) may be used. These terms are only intended to distinguish the component from other components, and the nature, order, sequence, or number of the components are not limited by the terms.

When a component is described as being “connected,” “coupled,” “joined,” or “attached” to another component, it should be understood that that the component can be directly connected, coupled, joined, or attached to that other component, but that other components may also be interposed between the components which can be indirectly connected, coupled, joined, or attached, unless otherwise expressly stated.

When a component or layer is described as “contacting” or “overlapping” another component or layer, it should be understood that the component or layer may directly contact or overlap the other component or layer, but that other components may also be interposed between the components that may indirectly contact or overlap each other, unless specifically stated otherwise.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

“At least one” should be understood to include any combination of one or more of the associated components. For example, “at least one of the first, second, and third components” could be understood to include any combination of two or more of the first, second, and third components, as well as the first, second, or third components.

A “first direction,” “second direction,” “third direction,” “X-axis direction,” “Y-axis direction” and “Z-axis direction” should not be interpreted as merely geometric relationships in which the relationship between them is perpendicular to each other, but may mean a broader directionality within the scope in which the configuration of the present disclosure can function functionally.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

The features of various embodiments of the present disclosure can be partially or entirely adhered to or combined with each other and can be interlocked and operated in technically various ways, and the embodiments can be carried out independently of or in association with each other.

Hereinafter, a display apparatus according to exemplary embodiments of the present disclosure will be described in detail with reference to accompanying drawings.

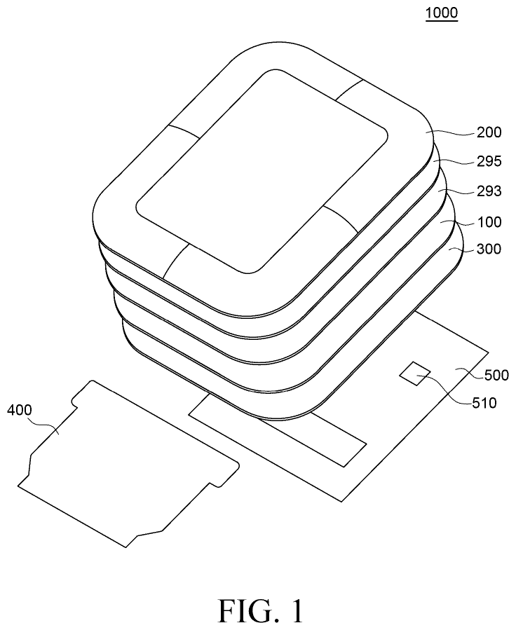

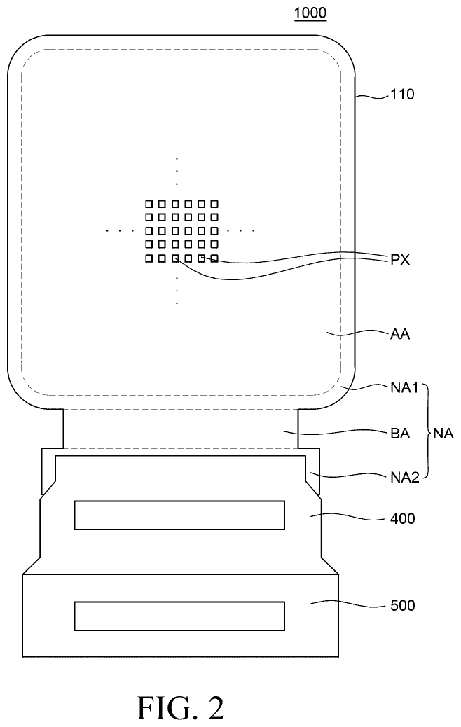

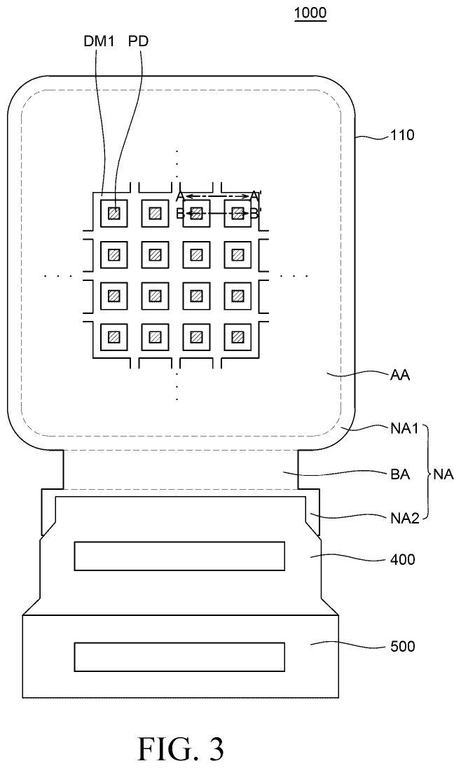

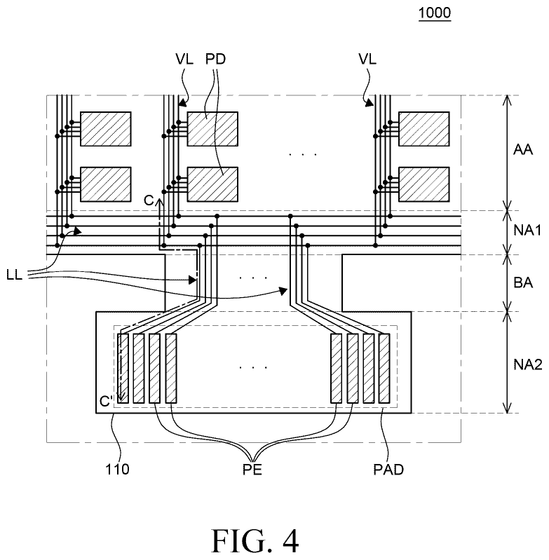

FIG. 1 is an exploded perspective view illustrating a display apparatus according to an exemplary embodiment of the present disclosure. FIG. 2 is a plan view of a display apparatus according to an exemplary embodiment of the present disclosure. FIG. 3 is a plan view of a display apparatus according to an exemplary embodiment of the present disclosure. FIG. 4 is an enlarged view of a display apparatus according to an exemplary embodiment of the present disclosure.

Referring to FIGS. 1 to 4, a display apparatus 1000 according to an exemplary embodiment of the present disclosure may include a display panel 100, a polarization layer 293, an adhesive layer 295, a cover member 200, a support substrate 300, a flexible circuit board 400, and a printed circuit board 500.

For example, the display panel 100 of the display apparatus 1000 may include a substrate 110. The substrate 110 may be a member which supports other components of the display apparatus 1000. The substrate 110 may be formed of an insulating material. For example, the substrate 110 may be formed of glass or resin. Further, the substrate 110 may also be formed of a material having a flexibility. For example, the substrate 110 may be formed of a plastic material having flexibility, such as polyimide (PI). However, the exemplary embodiments of the present disclosure are not limited thereto.

The display panel 100 may be configured to provide information, videos, and/or images to users. For example, the display panel 100 may include an active area AA and a non-active area NA. For example, the substrate 110 may include an active area AA and a non-active area NA. However, the active area AA and the non-active area NA may not be mentioned to be limited only to the substrate 110, but may be mentioned for the entire display apparatus 1000.

The active area AA may be an area where images are displayed. The active arca AA may include a plurality of pixels PX. Each of the plurality of pixels PX may be configured by a plurality of sub pixels. A plurality of micro LEDs may be disposed in each of the plurality of sub pixels. The plurality of micro LEDs may be configured in different manners depending on the type of the display apparatus 1000.

The non-active area NA may be an area where no image is displayed. In the non-active area NA, various wiring lines and circuits for driving the plurality of pixels PX of the active arca AA may be disposed. For example, in the non-active area NA, various wiring lines and driving circuits may be mounted and a pad unit PAD to which an integrated circuit and a printed circuit are connected may be disposed, but the exemplary embodiments of the present disclosure are not limited thereto.

For example, the driving circuit may be a data driving circuit and/or a gate driving circuit, but the exemplary embodiments of the present disclosure are not limited thereto. Wiring lines through which a control signal for controlling driving circuits is supplied may be disposed. For example, the control signal may include various timing signals including a clock signal, an input data enable signal, and synchronization signals, but the exemplary embodiments of the present disclosure are not limited thereto. The control signal may be received through the pad unit PAD. For example, in the non-active area NA, link lines LL may be disposed to transmit signals. For example, driving components, such as the flexible circuit board 400 and the printed circuit board 500, may be connected to the pad unit PAD.

According to the present disclosure, the non-active area NA may include a first non-active area NA1, a bending area BA, and a second non-active area NA2. For example, the first non-active area NA1 may be an area which encloses at least a part of the active area AA. The bending arca BA may be an area extending from at least one side, among a plurality of sides of the first non-active area NA1 and may be a bendable area. The second non-active area NA2 may be an arca extending from the bending area BA and the pad unit PAD may be disposed therein. For example, the bending area BA may be in a bent state and the other areas of the substrate 110 excluding the bending area BA may be in a flat state. In this case, as the bending area BA is bent, the second non-active area NA2 may be located on a rear surface of the active area AA. However, the exemplary embodiments of the present disclosure are not limited thereto.

The active area AA of the substrate 110 or the display apparatus 1000 may be configured with various shapes depending on a design of the display apparatus 1000. For example, the active area AA may be configured with a rectangular shape formed with four rounded corners, but the exemplary embodiments of the present disclosure are not limited thereto. As another example, the active area AA may be configured with a rectangular shape formed with four right-angled corners or a circular shape, but the exemplary embodiments of the present disclosure are not limited thereto.

According to the present disclosure, a width of the second non-active area NA2 in which the plurality of pad electrodes PE is disposed may be larger than a width of the bending area BA in which only a plurality of link lines LL is disposed. Further, a width of the active arca AA in which the plurality of sub pixels is disposed may be larger than a width of the bending arca BA in which only a plurality of link lines LL is disposed. Even though in the drawing, it is illustrated that the width of the bending area BA is smaller than a width of the other area of the substrate 110, the shape of the substrate 110 including the bending area BA is illustrative and the exemplary embodiments of the present disclosure are not limited thereto.

Referring to FIGS. 3 and 4, a plurality of pixel driving circuits PD may be disposed in the active area AA. The plurality of pixel driving circuits PD may be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD may include a power line and a signal line for controlling emission on/off of the micro LED and/or an emission time. For example, the plurality of pixel driving circuits PD may be driving drivers manufactured using a metal-oxide-silicon field effect transistor (MOSFET) manufacturing process on a semiconductor substrate, but the exemplary embodiments of the present disclosure are not limited thereto. The driving driver may include a plurality of pixel driving circuits PD and drive a plurality of sub pixels.

Referring to FIG. 3, a dam DM1 may be disposed between adjacent pixel driving circuits PD.

The dam DM1 may be disposed so as to enclose each of the pixel driving circuits PD. For example, the dam DM1 may be disposed in a matrix. For example, the dam DM1 may be a structure including a plurality of openings which is formed to overlap the pixel driving circuits PD.

In the meantime, even though in FIG. 3, it is illustrated that the dams DM1 are disposed in a matrix with the pixel driving circuits PD therebetween, the exemplary embodiments of the present disclosure are not limited thereto. For example, the dam DM1 may include a structure having a closed curve shape which encloses different pixel driving circuits PD.

Referring to FIG. 1 together, the flexible circuit board 400 and the printed circuit board 500 may be disposed below the display panel 100. The flexible circuit board 400 and the printed circuit board 500 may be disposed at least at one edge of the display panel 100, but the exemplary embodiments of the present disclosure are not limited thereto. One side of the flexible circuit board 400 may be attached to the display panel 100 and the other side may be attached to the printed circuit board 500, but the exemplary embodiments of the present disclosure are not limited thereto. The flexible circuit board 400 may be a flexible film, but the exemplary embodiments of the present disclosure are not limited thereto.

A pad unit PAD including a plurality of pad electrodes PE may be disposed in the second non-active arca NA2. In the pad unit PAD, a driving component including one or more flexible circuit boards (or flexible films) 400 and the printed circuit board 500 may be attached or bonded. The plurality of pad electrodes PE of the pad unit PAD may be electrically connected to one or more flexible circuit boards (or flexible films) 400 and transmit various signals (or powers) from the printed circuit board 500 and the flexible circuit board (or a flexible film) 400 to the plurality of pixel driving circuits PD of the active area AA.

The flexible circuit board (or flexible film) 400 may be a film on which various components are disposed on a base film having ductility. For example, driving ICs such as a gate driver IC or a data driver IC may be disposed in the flexible circuit board (or flexible film) 400, but the exemplary embodiments of the present disclosure are not limited thereto. The driving IC may be a component which processes data and driving signals to display images. The driving IC may be disposed by a chip on glass (COG), a chip on film (COF), or a tape carrier package (TCP) technique depending on a mounting method, but the exemplary embodiments of the present disclosure are not limited thereto. The flexible circuit board (or flexible film) 400 may be attached or bonded onto the plurality of pad electrodes PE through a conductive adhesive layer, but the exemplary embodiments of the present disclosure are not limited thereto.

The printed circuit board 500 may be a component which is electrically connected to one or more flexible circuit boards (or flexible films) 400 and supplies a signal to the driving IC. The printed circuit board 500 is disposed at one side of the flexible circuit board (or flexible film) 400 to be electrically connected to the flexible circuit board (or flexible film) 400. On the printed circuit board 500, various components for supplying various signals to the driving IC may be disposed. For example, on the printed circuit board 500, various components, such as a timing controller, a power source, a memory, or a processor, may be disposed. For example, the printed circuit board 500 may include a power management integrated circuit (PMIC), but the exemplary embodiments of the present disclosure are not limited thereto.

The printed circuit board 500 may include at least one hole 510, but the exemplary embodiments of the present disclosure are not limited thereto. An internal component which senses ambient light or temperature to be supplied to a plurality of sensors may be disposed in an arca corresponding to at least one hole 510. For example, the internal component may include an ambient light sensor (ALS) or a temperature sensor, but the exemplary embodiments of the present disclosure are not limited thereto. For example, the hole 510 may be a transmission hole, but the exemplary embodiments of the present disclosure are not limited thereto.

Referring to FIG. 1, a polarization layer 293 may be disposed on the display panel 100. The polarization layer 293 may suppress or reduce the influence on the micro LED caused by light generated from an external light source and entering the display panel 100.

A cover member 200 may be disposed on the polarization layer 293. The cover member 200 may be a member for protecting the display panel 100. The adhesive layer 295 may be disposed between the polarization layer 293 and the cover member 200. The cover member 200 may be attached to the display panel 100 using the adhesive layer 295. The adhesive layer 295 may include an optically clear adhesive (OCA), an optically clear resin (OCR), or a pressure sensitive adhesive (PSA), but the exemplary embodiments of the present disclosure are not limited thereto.

The support substrate 300 may be disposed between the display panel 100 and the printed circuit board 500. The support substrate 300 may reinforce a rigidity of the display panel 100. The support substrate 300 may be a back plate, but the exemplary embodiments of the present disclosure are not limited thereto.

Referring to FIGS. 1 to 4, the plurality of link lines LL may be disposed in the non-active area NA. The plurality of link lines LL may be wiring lines which transmit various signals from one or more flexible circuit boards (or flexible films) 400 and the printed circuit board 500 to the active area AA. The plurality of link lines LL extends from the plurality of pad electrodes PE of the second non-active arca NA2 toward the bending area BA and the first non-active area NA1 to be electrically connected to the plurality of driving lines VL of the active area AA. The plurality of pixel driving circuits PD may be supplied with signals from one or more flexible films (or flexible films) 400 and the printed circuit board 500 through the driving line VL of the active area AA and the link line LL of the non-active arca NA to be driven.

For example, the plurality of driving lines VL may be wiring lines for transmitting a signal output from the flexible circuit board (or flexible film) 400 and the printed circuit board 500 to the plurality of pixel driving circuits PD together with the plurality of link lines LL. The plurality of driving lines VL is disposed in the active area AA to be electrically connected to each of the plurality of pixel driving circuits PD. The plurality of driving lines VL extends toward the non-active area NA from the active area AA to be electrically connected to the plurality of link lines LL. Accordingly, a signal output from the flexible circuit board (or flexible film) 400 and the printed circuit board 500 may be transmitted to each of the plurality of pixel driving circuits PD through the plurality of link lines LL and the plurality of driving lines VL.

As the bending area BA is bent, parts of the plurality of link lines LL may be bent together. A stress is concentrated in the bent part of the link line LL, which may cause a crack on the link line LL. Accordingly, the plurality of link lines LL may be configured by a conductive material having excellent ductility to reduce the crack caused when the bending area BA is bent. For example, the plurality of link lines LL may be configured by a conductive material having excellent ductility, such as gold (Au), silver (Ag), or aluminum (Al), but the exemplary embodiments of the present disclosure are not limited thereto. Further, the plurality of link lines LL may be configured by one of various conductive materials used for the active area AA. For example, the plurality of link lines LL may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto. The plurality of link lines LL may be configured by a multi-layered structure including various conductive materials. For example, the plurality of link lines LL may be configured with a triple-layered structure of titanium (Ti)/aluminum (Al)/titanium (Ti), but the exemplary embodiments of the present disclosure are not limited thereto.

The plurality of link lines LL may be configured with various shapes to reduce a stress. At least parts of the plurality of link lines LL disposed on the bending area BA may extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA may extend in an inclined direction from one direction. As another example, at least parts of the plurality of link lines LL may be configured by various shapes of patterns. For example, at least parts of the plurality of link lines LL disposed on the bending area BA may have a shape in which a conductive pattern having at least one shape of a diamond shape, a rhombus shape, a trapezoidal wave shape, a triangular wave shape, a sawtooth wave shape, a sine wave shape, a circular shape, an omega (Ω) shape is repeatedly disposed. However, the exemplary embodiments of the present disclosure are not limited thereto. Accordingly, in order to minimize a stress concentrated on the plurality of link lines LL and a crack caused thereby, a shape of the plurality of link lines LL may be various shapes including the above-mentioned shapes, but the exemplary embodiments of the present disclosure are not limited thereto.

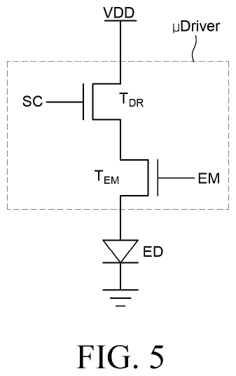

FIG. 5 is a view illustrating a circuit structure according to an exemplary embodiment of the present disclosure.

A pixel driving circuit PD may include a micro driver (μDriver). The micro LED (ED) is electrically connected to the micro driver (μDriver) of the pixel driving circuit PD to be driven. Even though in FIG. 4, it is illustrated that one micro LED (ED) is connected to one micro driver (μDriver), but the present disclosure is not limited thereto. For example, eight micro LEDs (ED) may be connected to one micro driver (μDriver). As another example, 16 micro LEDs (ED) may be connected to one micro driver (μDriver) or 32 micro LEDs (ED) or 64 micro LEDs (ED) may be simultaneously connected to one micro driver (μDriver). The micro LED (ED) may be a micro LED (μLED).

One micro driver (μDriver) may include a driving transistor T_{DR} and an emission transistor T_{EM}, but the exemplary embodiments of the present disclosure are not limited thereto.

For example, a high potential power voltage VDD may be applied to a first electrode of the driving transistor T_{DR} and a first electrode of the emission transistor T_{EM} may be connected to a second electrode, and a scan signal SC may be applied to a gate electrode. The scan signal SC applied to the gate electrode of the driving transistor T_{DR} may be a direct current (DC) power and a fixed reference voltage may be applied in every frame, but the exemplary embodiments of the present disclosure are not limited thereto.

The second electrode of the driving transistor T_{DR} may be connected to a first electrode of the emission transistor T_{EM}, the micro LED (ED) may be connected to a second electrode, and the emission signal EM may be applied to a gate electrode. The emission signal EM applied to the gate electrode of the emission transistor T_{EM} may be a pulse width modulation signal which changes in every frame, but the exemplary embodiments of the present disclosure are not limited thereto.

A first electrode of the micro LED (ED) may be connected to the second electrode of the emission transistor T_{EM} and a second electrode may be connected to the ground. For example, the first electrode may be an anode electrode and the second electrode may be a cathode electrode, but the exemplary embodiments of the present disclosure are not limited thereto.

Each of the driving transistor T_{DR} and the emission transistor T_{EM} may be an n-type transistor or a p-type transistor.

The driving transistor T_{DR} may be turned on by a scan signal applied from the timing controller T-CON to the micro driver (μDriver) and the emission transistor T_{EM} may be turned on by the emission signal EM. By doing this, the driving current is applied to the micro LED (ED) via the driving transistor T_{DR} and the emission transistor T_{EM} by the high potential power voltage VDD applied to the first electrode of the driving transistor T_{DR} so that the micro LED (ED) may emit light.

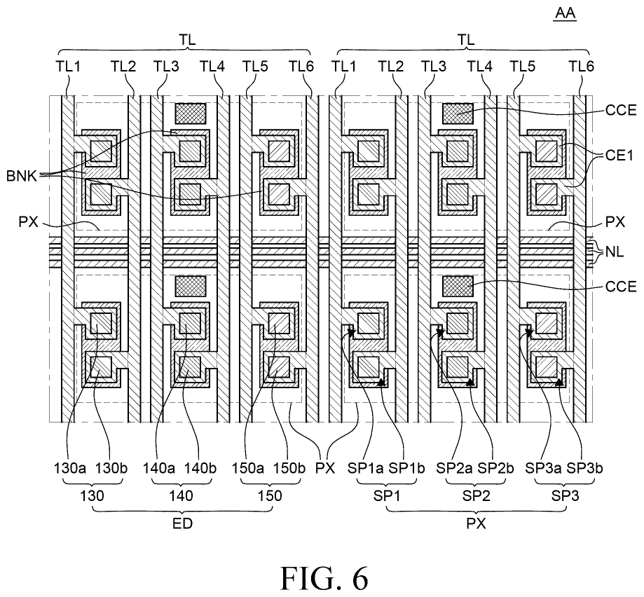

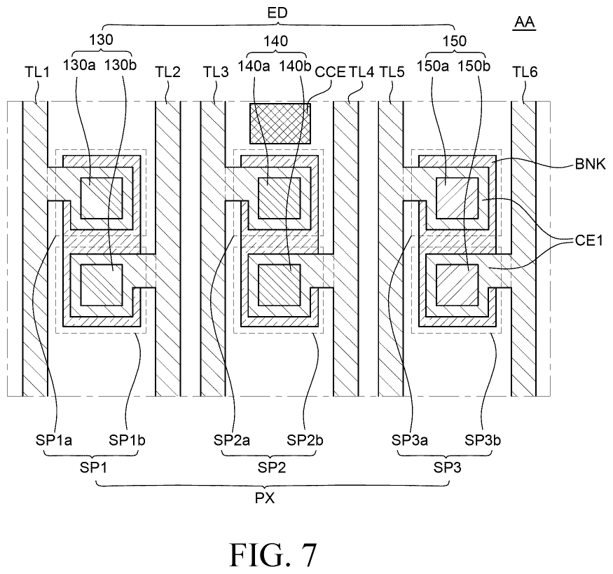

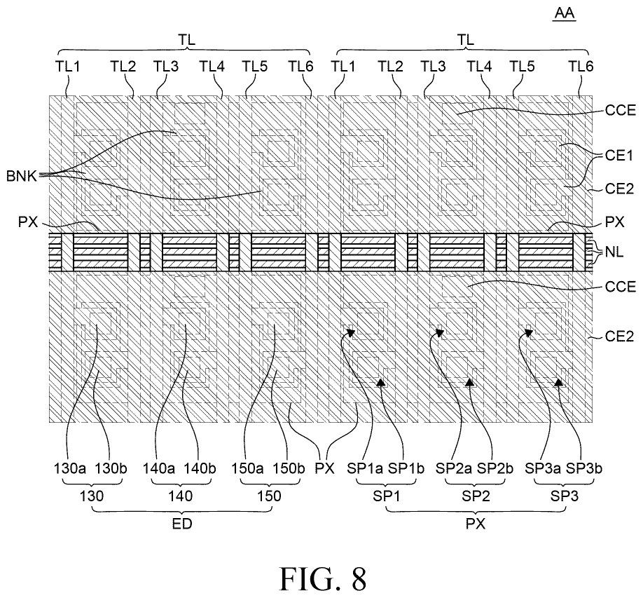

FIGS. 6 to 8 are plan views of a display apparatus according to an exemplary embodiment of the present disclosure. For example, FIG. 6 is an enlarged plan view of an active area including a plurality of pixels. For example, FIG. 7 is an enlarged plan view of an active area including one pixel. For example, FIG. 8 is an enlarged plan view of an active area including a plurality of pixels. In FIGS. 6 and 7, only a plurality of signal lines TL, a plurality of communication lines NL, a plurality of first electrodes CE1, a plurality of contact electrodes CCE, a plurality of banks BNK, and a plurality of micro LEDs (ED) are illustrated, but the exemplary embodiments of the present disclosure are not limited thereto. FIG. 8 is an enlarged plan view in which a plurality of second electrodes CE2 is additionally disposed to FIG. 6.

Referring to FIGS. 6 and 7, a plurality of pixels PX which is configured by a plurality of sub pixels may be disposed in the active area AA. Each of the plurality of sub pixels may include a micro LED (ED) and may independently emit light. The plurality of sub pixels may be disposed in a matrix by forming a plurality of rows and a plurality of columns, but the exemplary embodiments of the present disclosure are not limited thereto.

The plurality of sub pixels may include a first sub pixel SP1, a second sub pixel SP2, and a third sub pixel SP3. For example, any one of the first sub pixel SP1, the second sub pixel SP2, and the third sub pixel SP3 may be a red sub pixel, another may be a green sub pixel, and the third may be a blue sub pixel. The types of the plurality of sub pixels are illustrative, but the exemplary embodiments of the present disclosure are not limited thereto.

Each of the plurality of pixels PX may include one or more first sub pixels SPI, one or more second sub pixels SP2, and one or more third sub pixels SP3. For example, one pixel PX may include one pair of first sub pixels SP1, one pair of second sub pixels SP2, and one pair of third sub pixels SP3. One pair of first sub pixels SP1 may be configured by a 1-1st sub pixel SP1a and a 1-2nd sub pixel SP1b. One pair of second sub pixels SP2 may be configured by a 2-1st sub pixel SP2a and a 2-2nd sub pixel SP2b. One pair of third sub pixels SP3 may be configured by a 3-1st sub pixel SP3a and a 3-2nd sub pixel SP3b. For example, one pixel PX may include a 1-1st sub pixel SP1a and a 1-2nd sub pixel SP1b, a 2-1st sub pixel SP2a and a 2-2nd sub pixel SP2b, and a 3-1st sub pixel SP3a and a 3-2nd sub pixel SP3b, but the exemplary embodiments of the present disclosure are not limited thereto.

The plurality of sub pixels which forms one pixel PX may be disposed in various ways. For example, in one pixel PX, one pair of first sub pixels SP1 may be disposed on the same column, one pair of second sub pixels SP2 may be disposed on the same column, and one pair of third sub pixels SP3 may be disposed on the same column. The first sub pixels SP1, the second sub pixels SP2, and the third sub pixels SP3 may be disposed on the same row. A number and a placement of the plurality of sub pixels which configures one pixel PX are illustrative, but the exemplary embodiments of the present disclosure are not limited thereto.

The plurality of signal lines TL may be disposed in an area between the plurality of sub pixels. The plurality of signal lines TL may extend in the column direction between the plurality of sub pixels. The plurality of signal lines TL may be wiring lines which transmit an anode voltage from the pixel driving circuit PD to the plurality of sub pixels. For example, the plurality of signal lines TL may be electrically connected to the plurality of pixel driving circuits PD and the first electrodes CE1 of the plurality of sub pixels. The anode voltage output from the pixel driving circuit PD may be transmitted to the first electrode CE1 of the plurality of sub pixels through the plurality of signal lines TL. For example, the first electrode CE1 may be an electrode which is electrically connected to the anode electrode 134 of the micro LED (ED). Therefore, the anode voltage from the signal line TL may be transmitted to the anode electrode 134 of the micro LED (ED) through the first electrode CE1.

Accordingly, instead of the plurality of transistors and storage capacitors formed in each of the plurality of sub pixels, a pixel driving circuit PD in which a plurality of pixel circuits is integrated is used to simplify the structure of the display apparatus 1000. Further, a circuit which is disposed in each of the plurality of sub pixels is integrated in one pixel driving circuit PD so that highly efficient low power driving is possible.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to one pair of first sub pixels SP1, respectively. The third signal line TL3 and the fourth signal line TL4 may be electrically connected to one pair of second sub pixels SP2, respectively. The fifth signal line TL5 and the sixth signal line TL6 may be electrically connected to one pair of third sub pixels SP3, respectively.

The first signal line TL1 may be disposed on one of one pair of first sub pixels SP1 and the second signal line TL2 may be disposed on the other one of one pair of first sub pixels SP1. The first signal line TLI may be electrically connected to one first sub pixel SP1, between one pair of first sub pixels SP1, for example, to the first electrode CE1 of the 1-1st sub pixel SP1a. The second signal line TL2 may be electrically connected to the other first sub pixel SP1, between one pair of first sub pixels SP1, for example, to the first electrode CE1 of the 1-2nd sub pixel SP1b.

The third signal line TL3 may be disposed on one of one pair of second sub pixels SP2 and the fourth signal line TL4 may be disposed on the other one of one pair of second sub pixels SP2. For example, the third signal line TL3 may be disposed to be adjacent to the second signal line TL2. The third signal line TL3 may be electrically connected to one second sub pixel SP2, between one pair of second sub pixels SP2, for example, to the first electrode CE1 of the 2-1st sub pixel SP2a. The fourth signal line TL4 may be electrically connected to the other second sub pixel SP2, between one pair of second sub pixels SP2, for example, to the first electrode CE1 of the 2-2nd sub pixel SP2b.

The fifth signal line TL5 may be disposed on one of one pair of third sub pixels SP3 and the sixth signal line TL6 may be disposed on the other one of one pair of third sub pixels SP3. For example, the fifth signal line TL5 may be disposed to be adjacent to the fourth signal line TL4. The sixth signal line TL6 may be disposed to be adjacent to the first signal line TL1 connected to the adjacent pixel PX. The fifth signal line TL5 may be electrically connected to one third sub pixel SP3, between one pair of third sub pixels SP3, for example, to the first electrode CE1 of the 3-1st sub pixel SP3a. The sixth signal line TL6 may be electrically connected to the other third sub pixel SP3, between one pair of third sub pixels SP3, for example, to the first electrode CE1 of the 3-2nd sub pixel SP3b.

The plurality of signal lines TL may be formed of a conductive material. For example, the plurality of signal lines TL may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the plurality of signal lines TL may be formed with a multi-layered structure of conductive materials. For example, the plurality of signal lines TL may be formed with a multi-layered structure of titanium (Ti)/aluminum (Al)/titanium (Ti)/indium tin oxide (ITO), but the exemplary embodiments of the present disclosure are not limited thereto.

A plurality of communication lines NL may be disposed in an area between the plurality of pixels PX. The plurality of communication lines NL may be disposed to extend in the row direction in an area between the plurality of pixels PX. The plurality of communication lines NL is disposed in the area between the plurality of second electrodes CE2 and may not overlap the plurality of second electrodes CE2. For example, the plurality of communication lines NL may be wiring lines used for short distance communication, such as near field communication (NFC). The plurality of communication lines NL may serve as antennas. For example, the plurality of communication lines NL may be a plurality of connection lines, but the exemplary embodiments of the present disclosure are not limited thereto.

According to the present disclosure, a bank BNK may be disposed in each of the plurality of sub pixels. The plurality of banks BNK may be structures in which the plurality of micro LEDs (ED) is seated. The plurality of banks BNK may guide a position of the plurality of micro LEDs (ED) during a transfer process of transferring the plurality of micro LEDs (ED) to the display apparatus 1000. The plurality of micro LEDs (ED) may be transferred onto the plurality of banks BNK in the transfer process of the plurality of micro LEDs (ED). The plurality of banks BNK may be a bank pattern or a structure, but the exemplary embodiments of the present disclosure are not limited thereto.

A bank BNK of the first sub pixel SP1, a bank BNK of the second sub pixel SP2, and a bank BNK of the third sub pixel SP3 may be disposed to be spaced apart from each other. The bank BNK of the first sub pixel SP1, the bank BNK of the second sub pixel SP2, and the bank BNK of the third sub pixel SP3 may be configured to be separated from each other. Therefore, the banks BNK of the first sub pixel SP1, the second sub pixel SP2, and the third sub pixel SP3 to which different types of micro LEDs (ED) are transferred may be easily identified.

In the meantime, in consideration of a design, such as a transfer process requirement, only one sub pixel may be disposed in one bank BNK. For example, a bank BNK of the 1-1st sub pixel SP1a and a bank BNK of the 1-2nd sub pixel SP1b may be spaced apart or separated from each other. The bank BNK of the 2-1st sub pixel SP2a and the bank BNK of the 2-2nd sub pixel SP2b may be spaced apart or separated from each other. The bank BNK of the 3-1st sub pixel SP3a and the bank BNK of the 3-2nd sub pixel SP3b may be spaced apart or separated from each other. However, the bank BNK may be formed in various forms without being limited thereto and the exemplary embodiments of the present disclosure are not limited thereto.

For example, the plurality of banks BNK may be formed of an organic insulating material. The plurality of banks BNK may be configured by a single layer or a double layer of an organic insulating material. For example, the plurality of banks BNK may be configured by a photo resist, polyimide (PI), or acrylic material, but the exemplary embodiments of the present disclosure are not limited thereto.

The first electrode CE1 may be disposed in each of the plurality of sub pixels. The first electrode CE1 may be disposed on the bank BNK. For example, each of the first electrode CE1 may be disposed on a top surface and a side surface of the plurality of banks BNK.

The first electrode CE1 may be electrically connected to one signal line TL, among the plurality of signal lines TL. At least a part of the first electrode CE1 extends to the outside of the bank BNK to be electrically connected to the signal line TL which is the most adjacent to the first electrode CE1. For example, a part of the first electrode CE1 of the 1-1st sub pixel SP1a extends to one area of the 1-1st sub pixel SP1a to be electrically connected to the first signal line TL1. A part of the first electrode CE1 of the 1-2nd sub pixel SP1b extends to the other area of the 1-2nd sub pixel SP1b to be electrically connected to the second signal line TL2. A part of the first electrode CE1 of the 2-1st sub pixel SP2a extends to one area of the 2-1st sub pixel SP2a to be electrically connected to the third signal line TL3. A part of the first electrode CE1 of the 2-2nd sub pixel SP2b extends to the other area of the 2-2nd sub pixel SP2b to be electrically connected to the fourth signal line TL4. A part of the first electrode CE1 of the 3-1st sub pixel SP3a extends to one area of the 3-1st sub pixel SP3a to be electrically connected to the fifth signal line TL5. A part of the first electrode CE1 of the 3-2nd sub pixel SP3b extends to the other area of the 3-2nd sub pixel SP3b to be electrically connected to the sixth signal line TL6.

The first electrode CE1 may be electrically connected to the anode electrode 134 of the micro LED (ED) and transmit an anode voltage from the pixel driving circuit PD to the micro LED (ED) through the signal line TL. Different voltages may be applied to the first electrodes CE1 of the plurality of sub pixels depending on the image to be displayed. For example, different voltages may be applied to the first electrodes CE1 of the plurality of sub pixels. Therefore, the first electrode CE1 may be a pixel electrode, but the exemplary embodiments of the present disclosure are not limited thereto.

The first electrode CE1 may be configured by a conductive material. For example, the first electrode CE1 may be integrally configured with the plurality of signal lines TL. For example, the first electrode CE1 may be configured by the same conductive material as the plurality of signal lines TL, but the exemplary embodiments of the present disclosure are not limited thereto. For example, the first electrode CE1 may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the first electrode CE1 may be configured by a multi-layered structure of conductive materials. For example, the plurality of first electrodes CE1 may be configured by a multi-layered structure of titanium (Ti)/aluminum (Al)/titanium (Ti)/indium tin oxide (ITO), but the exemplary embodiments of the present disclosure are not limited thereto.

The micro LED (ED) may be disposed in each of the plurality of sub pixels. The plurality of micro LEDs (ED) may be any one of a light-emitting diode or a micro light-emitting diode (micro LED), but the exemplary embodiments of the present disclosure are not limited thereto. The plurality of micro LEDs (ED) may be disposed on the bank BNK and the first electrode CE1. The plurality of micro LEDs (ED) may be disposed on the first electrode CE1 and may be electrically connected to the first electrode CE1. Accordingly, the micro LED (ED) may be applied with an anode voltage from the pixel driving circuit PD through the signal line TL and the first electrode CE1 to emit light.

The plurality of micro LEDs (ED) may include a first micro LED 130, a second micro LED 140, and a third micro LED 150. The first micro LED 130 may be disposed in the first sub pixel SP1. The second micro LED 140 may be disposed in the second sub pixel SP2. The third micro LED 150 may be disposed in the third sub pixel SP3. For example, any one of the first micro LED 130, the second micro LED 140, and the third micro LED 150 may be a red micro LED, another may be a green micro LED, and the third may be a blue micro LED, but the exemplary embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the exemplary embodiments of the present disclosure are not limited thereto.

The first micro LED 130 may include a 1-1st micro LED 130a disposed in the 1-1st sub pixel SP1a and a 1-2ndmicro LED 130b disposed in the 1-2nd sub pixel SP1b. The second micro LED 140 may include a 2-1st micro LED 140a disposed in the 2-1st sub pixel SP2a and a 2-2nd micro LED 140b disposed in the 2-2nd sub pixel SP2b. The third micro LED 150 may include a 3-1st micro LED 150a disposed in the 3-1st sub pixel SP3a and a 3-2nd micro LED 150b disposed in the 3-2nd sub pixel SP3b.

Referring to FIGS. 6, 7 and 8 together, the second electrode CE2 may be disposed in each of the plurality of sub pixels. The second electrode CE2 may be disposed on the micro LED (ED). The second electrode CE2 may be electrically connected to the pixel driving circuit PD through the plurality of contact electrodes CCE.

For example, the second electrode CE2 is electrically connected to the cathode electrode 135 of the micro LED (ED) to transmit a cathode voltage from the pixel driving circuit PD to the micro LED (ED). The same cathode voltage may be applied to the second electrodes CE2 of the plurality of sub pixels, respectively. For example, the same voltage may be applied to the second electrode CE2 of each of the plurality of sub pixels and the cathode electrode 135 of the micro LED (ED). Therefore, the second electrode CE2 may be a common electrode, but the exemplary embodiments of the present disclosure are not limited thereto.

At least some of the plurality of sub pixel may share the second electrode CE2. At least some of the second electrodes CE2 of the plurality of sub pixels may be electrically connected to each other. As the same voltage is applied to the second electrode CE2, the second electrodes CE2 of at least some sub pixels may be shared and used. For example, the second electrodes CE2 of at least some pixels PX, among the plurality of pixels PX disposed on the same row, may be connected to each other. For example, one second electrode CE2 may be disposed in the plurality of pixels PX. One second electrode CE2 may be disposed in every n sub pixels.

For example, some of the second electrodes CE2 of the plurality of sub pixels may be spaced apart or separated from each other. For example, a second electrode CE2 connected to pixels PX in an n-th row and a second electrode CE2 connected to pixels PX in an n+1-th row may be spaced apart or separated from each other. For example, the plurality of second electrodes CE2 may be spaced apart from each other with the plurality of communication lines NL extending in the row direction therebetween. Accordingly, the number of the plurality of sub pixels may be larger than the number of the plurality of second electrodes CE2. As another example, all the second electrodes CE2 of the plurality of sub pixels are connected to each other so that only one second electrode CE2 may be disposed on the substrate 110, but the exemplary embodiments of the present disclosure are not limited thereto.

The plurality of second electrodes CE2 may be configured by a transparent conductive material, but the exemplary embodiments of the present disclosure are not limited thereto. The plurality of second electrodes CE2 is configured by a transparent conductive material so that light emitted from the micro LED (ED) may travel toward the top of the second electrode CE2. For example, the second electrode CE2 may be configured by a transparent conductive material, such as indium tin oxide (ITO), indium zinc oxide (IZO), indium gallium zinc oxide (IGZO), but the exemplary embodiments of the present disclosure are not limited thereto.

A plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap a plurality of contact electrodes CCE.

For example, the plurality of contact electrodes CCE may be electrically connected to the plurality of second electrodes CE2. The plurality of contact electrodes CCE is disposed between the substrate 110 and the plurality of second electrodes CE2 to transmit a cathode voltage from the pixel driving circuit PD to the second electrode CE2.

For example, when a micro LED (ED) is used as the micro LED, a plurality of micro LEDs is formed on a wafer and the micro LED is transferred onto the substrate 110 of the display apparatus 1000 to manufacture the display apparatus 1000. However, during the process of transferring the plurality of micro LEDs (ED) having a micro size from the wafer to the substrate 110, various defects may be caused. For example, in some sub pixels, a non-transfer defect in which the micro LED is not transferred may occur and in the other sub pixel, a defect that the micro LED (ED) is transferred in a wrong position may occur due to the alignment error. Further, even though the transfer process is normally performed, the transferred micro LED (ED) may be defective. Accordingly, in consideration of the defects during the transfer process of the plurality of micro LEDs (ED), a plurality of micro LEDs which emits the same color light may be transferred into one sub pixel. A lighting test for the plurality of micro LEDs (ED) is performed and only one micro LED (ED) which is finally determined to be normal may be used.

For example, the 1-1st micro LED 130a and the 1-2nd micro LED 130b are transferred to one pixel PX together and defects thereof may be tested. If both the 1-1st micro LED 130a and the 1-2nd micro LED 130b are determined to be normal, only the 1-1st micro LED 130a may be used, but the 1-2nd micro LED 130b may not be used. As another example, if only the 1-2nd micro LED 130b between the 1-1st micro LED 130a and the 1-2nd micro LED 130b is determined to be normal, the 1-1st micro LED 130a may not be used, but only the 1-2nd micro LED 130b may be used. Accordingly, even though the plurality of micro LEDs (ED) which emits the same color light is transferred into one pixel PX, finally, only one micro LED (ED) may be used.

Therefore, any one of one pair of micro LEDs (ED) may be a main (or primary) micro LED (ED) and the other micro LED (ED) may be a redundancy micro LED (ED). The redundancy micro LED (ED) may be an extra micro LED (ED) which is transferred to prepare for a defect of the main micro LED (ED). When the main micro LED (ED) is defective, the redundancy micro LED (ED) may be used instead. Accordingly, the main micro LED (ED) and the redundancy micro LED (ED) are transferred together to one pixel PX so that the degradation of the display quality due to the defects of the main micro LED (ED) and the redundancy micro LED (ED) may be minimized.

For example, a 1-1st micro LED 130a, a 2-1st micro LED 140a, and a 3-1st micro LED 150a which are transferred into one pixel PX may be used as main micro LEDs (ED) and a 1-2nd micro LED 130b, a 2-2nd micro LED 140b, and a 3-2nd micro LED 150b may be used as redundancy micro LEDs (ED).

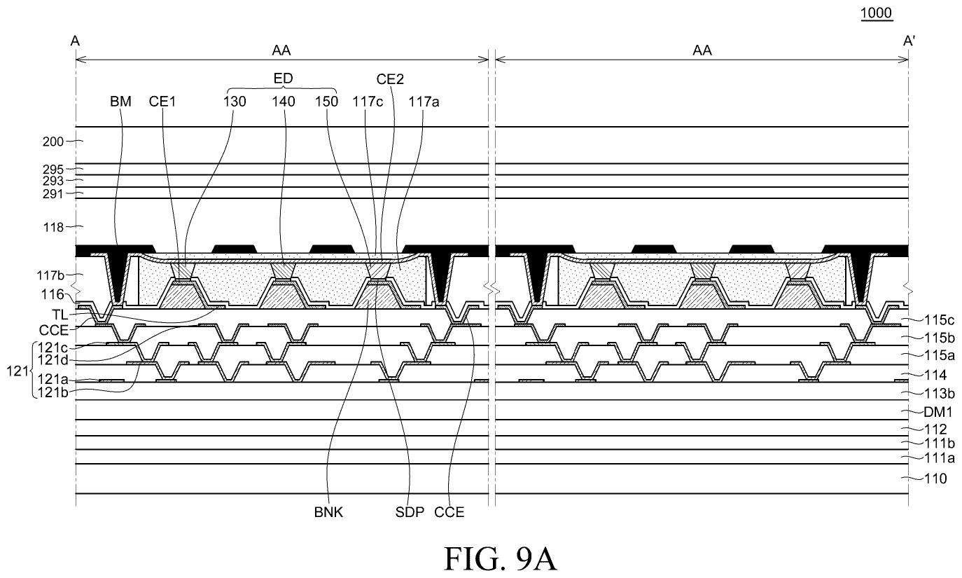

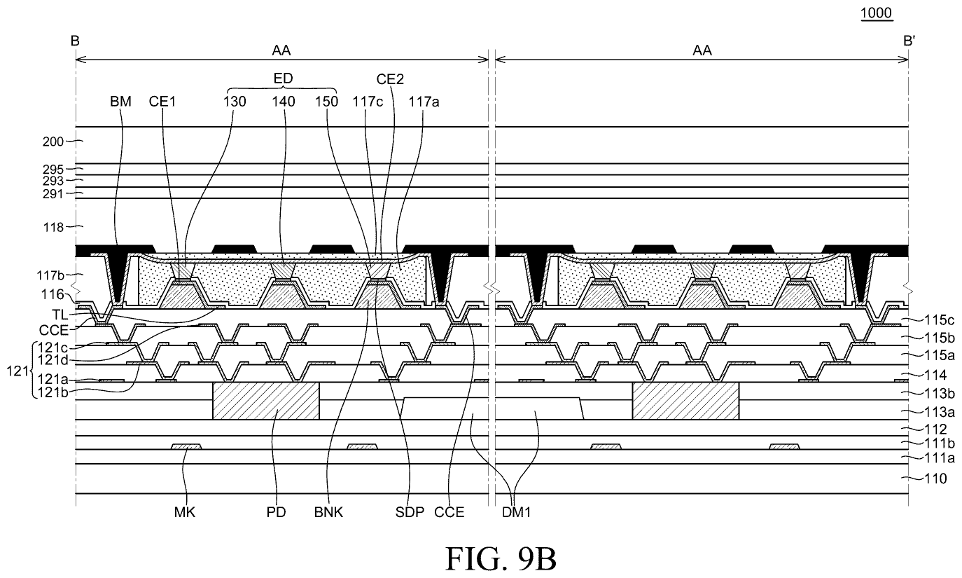

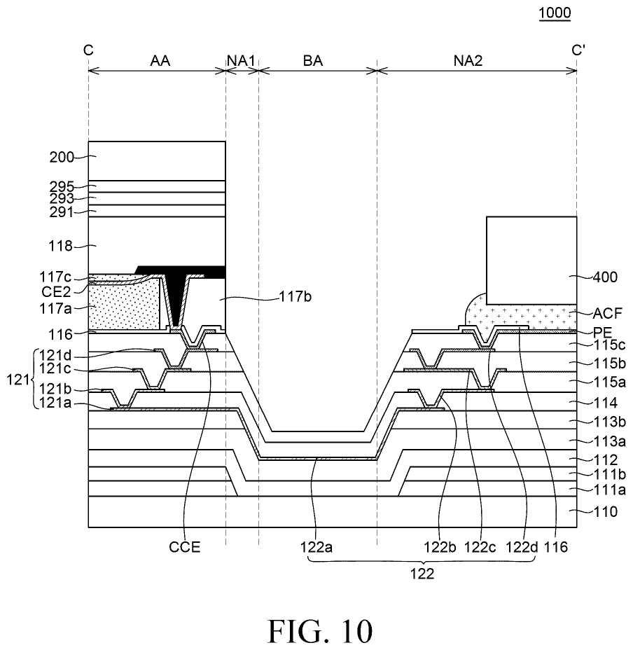

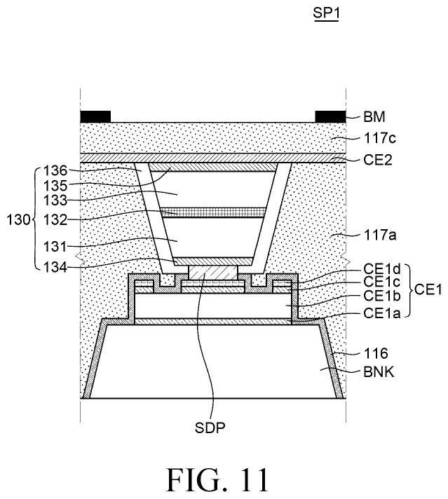

FIG. 9A is a cross-sectional view taken along A-A′ of FIG. 3. FIG. 9B is a cross-sectional view taken along B-B′ of FIG. 3. FIG. 10 is a cross-sectional view taken along C-C′ of FIG. 4. FIG. 11 is a cross-sectional view of a display apparatus according to an exemplary embodiment of the present disclosure. FIGS. 9A and 9B are cross-sectional views of an active area AA according to an exemplary embodiment of the present disclosure. FIG. 10 is a cross-sectional view of an active area AA, a first non-active area NA1, a bending area BA, and a second non-active area NA2 according to an exemplary embodiment of the present disclosure. In the meantime, for the convenience of illustration, in FIG. 4, it is illustrated that a cross-sectional line of C-C′ and a driving line VL and a link line LL do not overlap, but the cross-sectional line C-C′ of FIG. 4 is provided to represent the same position as the adjacent driving line VL and link line LL. FIG. 11 is an enlarged cross-sectional view of a first sub pixel SP1.

Referring to FIGS. 9A to 10, a first buffer layer 111a and a second buffer layer 111b may be disposed in the remaining area of the substrate 110 excluding the bending area BA.

The first buffer layer 111a and the second buffer layer 111b may be disposed in the active area AA, the first non-active area NA1, and the second non-active area NA2. The first buffer layer 111a and the second buffer layer 111b may reduce permeation of moisture or impurities through the substrate 110. The first buffer layer 111a and the second buffer layer 111b may be formed of an inorganic insulating material. For example, the first buffer layer 111a and the second buffer layer 111b may be configured by a single layer or multiple layers of silicon oxide (SiOₓ) or silicon nitride (SiNₓ), but the exemplary embodiments of the present disclosure are not limited thereto.

For example, the first buffer layer 111a and the second buffer layer 111b on the bending area BA may be partially removed. A top surface of the substrate 110 located in the bending area BA may be exposed from the first buffer layer 111a and the second buffer layer 111b. The first buffer layer 111a and the second buffer layer 111b which are formed of an inorganic insulating material are removed from the bending area BA to minimize cracks of the first buffer layer 111a and the second buffer layer 111b which may be generated during the bending.

A plurality of alignment keys MK may be disposed between the first buffer layer 111a and the second buffer layer 111b. The plurality of alignment keys MK may be configured to identify a position of the pixel driving circuit PD during the manufacturing process of the display apparatus 1000. For example, the plurality of alignment keys MK may be configured to align a position of the pixel driving circuit PD which is transferred onto the adhesive layer 112. As another example, the plurality of alignment keys MK may be omitted.

The adhesive layer 112 may be disposed on the second buffer layer 111b. The adhesive layer 112 may be disposed in the active area AA, the first non-active area NA1, the bending area BA, and the second non-active area NA2. As another example, in the non-active area NA including the bending area BA, at least a part of the adhesive layer 112 may be removed. For example, the adhesive layer 112 may be formed of any one of adhesive polymer, epoxy resin, UV curable resin, polyimide based, acrylate based, urethane based, and polydimethylsiloxane (PDMS), but the exemplary embodiments of the present disclosure are not limited thereto.

The pixel driving circuit PD may be disposed on the adhesive layer 112 in the active arca AA. When the pixel driving circuit PD is implemented as a driving driver, the driving driver may be mounted on the adhesive layer 112 by the transfer process, but the exemplary embodiments of the present disclosure are not limited thereto.

The dam DM1 may be disposed on the adhesive layer 112 in the active arca AA. For example, the dam DM1 may be in contact with the top surface of the adhesive layer 112 together with the plurality of pixel driving circuits PD in the active area AA. Therefore, the dam DM1 may be disposed on the same layer as the plurality of pixel driving circuits PD.

The dam DM1 may be formed of an organic material. For example, the dam DM1 may be configured by a photo resist, polyimide (PI), or photo acrylic material, but the exemplary embodiments of the present disclosure are not limited thereto.

The dam DM1 may be a structure including an opening which overlaps the plurality of pixel driving circuits PD and the alignment key MK.

The alignment key MK may be disposed between the dam DM1 and the pixel driving circuit PD. Referring to FIG. 9B, the dam DM1 may be disposed so as not to overlap the alignment key MK disposed in a peripheral area of the pixel driving circuit PD. For example, the alignment key MK may be disposed in a peripheral area of the pixel driving circuit PD. Therefore, at least one pair of alignment keys MK may be disposed between the adjacent pixel driving circuits PD. At this time, a width of the dam DM1 between adjacent pixel driving circuits PD may be smaller than a distance between the alignment keys MK disposed between adjacent pixel driving circuits PD. Accordingly, the dam DM1 may be disposed between the plurality of alignment keys MK.

The dam DM1 may be disposed to overlap at least one pixels PX, among the plurality of pixels PX. For example, the dam DM1 may be disposed to overlap the plurality of micro LEDs (ED). Further, the dam DM1 may be disposed to overlap at least some of the plurality of first connection lines 121.

A first protection layer 113a and a second protection layer 113b may be disposed on a top surface of the adhesive layer 112, a top surface or a side surface of the dam DM1 and the pixel driving circuit PD. The first protection layer 113a and the second protection layer 113b may be disposed so as to enclose the side surface of the pixel driving circuit PD, but the exemplary embodiments of the present disclosure are not limited thereto. For example, the second protection layer 113b may be disposed so as to cover at least a part of a top surface of the pixel driving circuit PD. Further, the second protection layer 113b may be disposed so as to cover at least a part of the top surface of the dam DM1. In the meantime, the first protection layer 113a and the second protection layer 113b may fill a space between the pixel driving circuit PD and the dam DM1. For example, the first protection layer 113a and the second protection layer 113b may cover the side surface of the dam DM1 and the side surface of the pixel driving circuit PD.

For example, at least one of the first protection layer 113a and the second protection layer 113b disposed on the bending area BA may be omitted. For example, the first protection layer 113a may be entirely disposed in the active area AA and the non-active area NA and the second protection layer 113b may be partially disposed in the active area AA, the first non-active area NA1, and the second non-active area NA2. For example, a part of the second protection layer 113b in the bending area BA may be removed. However, the exemplary embodiments of the present disclosure are not limited thereto.

The first protection layer 113a and the second protection layer 113b may be configured by an organic insulating material, but the exemplary embodiments of the present disclosure are not limited thereto. For example, the first protection layer 113a and the second protection layer 113b may be configured by a photo resist, polyimide (PI), or photo acrylic material, but the exemplary embodiments of the present disclosure are not limited thereto. For example, the first protection layer 113a and the second protection layer 113b may be over coating layers or insulating layers, but the exemplary embodiments of the present disclosure are not limited thereto.

According to the present disclosure, in the active area AA, the plurality of first connection lines 121 may be disposed on the second protection layer 113b. The plurality of first connection lines 121 may be wiring lines which electrically connect the pixel driving circuit PD to the other component. For example, the pixel driving circuit PD may be electrically connected to the plurality of signal lines TL and the plurality of contact electrodes CCE through the plurality of first connection lines 121. For example, the plurality of first connection lines 121 may include a 1-1st connection line 121a, a 1-2nd connection line 121b, a 1-3nd connection line 121c, and a 1-4-th connection line 121b, but the exemplary embodiments of the present disclosure are not limited thereto. Each of the plurality of first connection lines 121 refers to a signal line disposed on the same layer and the plurality of first connection lines 121 may include signal lines to which different signals are applied.

For example, the plurality of 1-1st connection lines 121a may be disposed on the second protection layer 113b. The plurality of 1-1st connection lines 121a may be electrically connected to the pixel driving circuit PD. The plurality of 1-1st connection lines 121a may transmit a voltage output from the pixel driving circuit PD to the first electrode CE1 or the second electrode CE2.

At least some of the plurality of 1-1st connection lines 121a may be disposed on the dam DM1. At least some of the plurality of 1-1st connection lines 121a may be disposed to overlap the dam DM1.

For example, a third protection layer 114 may be disposed on the second protection layer 113b. The third protection layer 114 may be entirely disposed in the active area AA and the non-active area NA. In the bending area BA, the third protection layer 114 may cover a side surface of the second protection layer 113b and the top surface of the first protection layer 113a. The third protection layer 114 may be configured by an organic insulating material. For example, the third protection layer 114 may be configured by a photo resist, polyimide (PI), or photo acrylic material, but the exemplary embodiments of the present disclosure are not limited thereto. For example, the first protection layer 113a, the second protection layer 113b, and the third protection layer 114 may be configured by the same material, but the exemplary embodiments of the present disclosure are not limited thereto.

The plurality of 1-2nd connection lines 121b may be disposed on the third protection layer 114. The plurality of 1-2nd connection lines 121b may be indirectly or directly connected to the pixel driving circuit PD. For example, a part of the 1-2nd connection line 121b may be directly connected to the pixel driving circuit PD through a contact hole of the third protection layer 114. The other part of the 1-2nd connection line 121b may be electrically connected to the 1-1st connection line 121a through the contact hole of the third protection layer 114. However, the exemplary embodiments of the present disclosure are not limited thereto. A voltage output from the pixel driving circuit PD may be transmitted to the first electrode CE1 or the second electrode CE2 through a connection line other than the plurality of 1-2nd connection lines 121b.

At least some of the plurality of 1-2nd connection lines 121b may be disposed on the dam DM1. At least some of the plurality of 1-2nd connection lines 121b may be disposed to overlap the dam DM1.

The first insulating layer 115a may be disposed on the plurality of 1-2nd connection lines 121b. The first insulating layer 115a may be entirely disposed in the active area AA and the non-active area NA, but the exemplary embodiments of the present disclosure are not limited thereto. The first insulating layer 115a may be configured by an organic insulating material, but the exemplary embodiments of the present disclosure are not limited thereto. For example, the first insulating layer 115a may be configured by a photo resist, polyimide (PI), or photo acrylic material, but the exemplary embodiments of the present disclosure are not limited thereto.

The plurality of 1-3nd connection lines 121c may be disposed on the first insulating layer 115a. The plurality of 1-3nd connection lines 121c may be electrically connected to the plurality of 1-2nd connection lines 121b. For example, the 1-3nd connection lines 121c may be electrically connected to the 1-2nd connection line 121b through a contact hole of the first insulating layer 115a.

At least some of the plurality of 1-3nd connection lines 121c may be disposed on the dam DM1. At least some of the plurality of 1-3nd connection lines 121c may be disposed to overlap the dam DM1.

The second insulating layer 115b may be disposed on the plurality of 1-3nd connection lines 121c. The second insulating layer 115b may be disposed in a remaining area excluding the bending area BA, but the exemplary embodiments of the present disclosure are not limited thereto. The second insulating layer 115b may be disposed in the active area AA, the first non-active area NA1, and the second non-active area NA2, but the exemplary embodiments of the present disclosure are not limited thereto. For example, a part of the second insulating layer 115b disposed in the bending area BA may be removed. The second insulating layer 115b may be configured by an organic insulating material, but the exemplary embodiments of the present disclosure are not limited thereto. For example, the second insulating layer 115b may be configured by a photo resist, polyimide (PI), or photo acrylic material, but the exemplary embodiments of the present disclosure are not limited thereto.

The plurality of 1-4-th connection lines 121d may be disposed on the second insulating layer 115b. The plurality of 1-4-th connection lines 121d may be electrically connected to the plurality of 1-3nd connection lines 121c. For example, the 1-4-th connection lines 121d may be electrically connected to the 1-3nd connection line 121c through a contact hole of the second insulating layer 115b.

At least some of the plurality of 1-4-th connection lines 121d may be disposed on the dam DM1. At least some of the plurality of 1-4-th connection lines 121d may be disposed to overlap the dam DM1.

A plurality of signal lines TL may be disposed on the third insulating layer 115c in the active area AA. The plurality of signal lines TL may be disposed to extend to an area between the plurality of banks BNK. For example, the plurality of signal lines TL may be disposed to be adjacent to any one of the plurality of banks BNK.

According to the present disclosure, in the non-active area NA, the plurality of second connection lines 122 may be disposed on the second protection layer 113b. The plurality of second connection lines 122 may be wiring lines which transmit a signal transmitted from the flexible circuit board (or flexible film) 400 and the printed circuit board 500 (see FIG. 1) to the pad unit PAD, to the pixel driving circuit PD of the active area AA. For example, the plurality of second connection lines 122 is electrically connected to the plurality of pad electrodes PE to be applied with a signal from the flexible circuit board (or flexible film) 400 and the printed circuit board 500. For example, the second connection lines 122 may transmit a signal which is transmitted to the pad unit PAD through the plurality of first connection lines 121 disposed in the active area AA to the pixel driving circuit PD.

For example, the plurality of second connection lines 122 extends toward the active area AA from the pad unit PAD to transmit a signal to the wiring line of the active area AA. In this case, the plurality of second connection lines 122 may serve as a link line LL. The plurality of second connection lines 122 may include a 2-1st connection line 122a, a 2-2nd connection line 122b, a 2-3nd connection line 122c, and a 2-4-th connection line 122d.

The plurality of 2-1st connection lines 122a may be disposed on the second protection layer 113b. The plurality of 2-1st connection lines 122a may extend from the second non-active arca NA2 to the bending area BA and the first non-active area NA1. The plurality of 2-1st connection lines 122a may transmit a signal transmitted from the flexible circuit board (or flexible film) 400 and the printed circuit board 500 to the pad unit PAD, to the pixel driving circuit PD of the active area AA.

The plurality of 2-2nd connection lines 122b may be disposed on the third protection layer 114. The plurality of 2-2nd connection lines 122b may be disposed in the second non-active area NA2. The 2-2nd connection line 122b may be electrically connected to the 2-1st connection line 122a through the contact hole of the third protection layer 114. Accordingly, a signal from the flexible circuit board (or flexible film) 400 and the printed circuit board 500 may be transmitted to the 2-1st connection line 122a through the 2-2nd connection line 122b.

The 2-3nd connection line 122c may be disposed on the first insulating layer 115a . The 2-3nd connection lines 122c may be disposed in the second non-active area NA2. The 2-3nd connection line 122c may be electrically connected to the 2-2nd connection line 122b through a contact hole of the first insulating layer 115a. Accordingly, a signal from the flexible circuit board (or flexible film) 400 and the printed circuit board 500 may be transmitted to the 2-1st connection line 122a through the 2-3nd connection line 122c and the 2-2nd connection line 122b.

The 2-4-th connection line 122d may be disposed on the second insulating layer 115b. The 2-4-th connection line 122d may be disposed in the second non-active area NA2. The 2-4-th connection line 122d may be electrically connected to the 2-3nd connection line 122c through a contact hole of the second insulating layer 115b. Accordingly, a signal from the flexible circuit board (or flexible film) 400 and the printed circuit board 500 may be transmitted to the 2-1st connection line 122a through the 2-4-th connection line 122d, the 2-3nd connection line 122c, and the 2-2nd connection line 122b.

The plurality of first connection lines 121 and the plurality of second connection lines 122 may be formed of any one of a conductive material having excellent ductility or various conductive materials used for the active area AA. For example, the second connection line 122 which is partially disposed in the bending area BA may be configured by a conductive material having excellent ductility, such as gold (Au), silver (Ag), or aluminum (Al), but the exemplary embodiments of the present disclosure are not limited thereto. As another example, the plurality of first connection lines 121 and the plurality of second connection lines 122 may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto.

The third insulating layer 115c may be disposed on the plurality of first connection lines 121 and the plurality of second connection lines 122. The third insulating layer 115c may be disposed in a remaining area excluding the bending area BA, but the exemplary embodiments of the present disclosure are not limited thereto. The third insulating layer 115c may be disposed in the active area AA, the first non-active area NA1, and the second non-active area NA2. A part of the third insulating layer 115c disposed in the bending area BA may be removed. The third insulating layer 115c may be configured by an organic insulating material, but the exemplary embodiments of the present disclosure are not limited thereto. For example, the third insulating layer 115c may be configured by a photo resist, polyimide (PI), or photo acrylic material, but the exemplary embodiments of the present disclosure are not limited thereto. A plurality of banks BNK may be disposed on the third insulating layer 115c in the active area AA. The plurality of banks BNK may be disposed so as to overlap each of the plurality of sub pixels. One or more micro LEDs (ED) which emit the same color light may be disposed above each of the plurality of banks BNK.

A plurality of contact electrodes CCE may be disposed on the third insulating layer 115c in the active area AA. The plurality of contact electrodes CCE may supply a cathode voltage from the pixel driving circuit PD to the second electrode CE2.

The first electrode CE1 may be disposed on the bank BNK. For example, the first electrode CE1 may be disposed to extend toward the top of the bank BNK from the adjacent signal line TL. The first electrode CE1 may be disposed on the top surface of the bank BNK and the side surface of the bank BNK. For example, the first electrode CE1 may be disposed to extend from the signal line TL on the top surface of the third insulating layer 115c to the side surface of the bank BNK and the top surface of the bank BNK.

Referring to FIG. 11, the first electrode CE1 may be configured by a plurality of conductive layers. For example, the first electrode CE1 may include a first conductive layer CE1a, a second conductive layer CE1b, a third conductive layer CE1c, and a fourth conductive layer CE1d, but the exemplary embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may be configured by titanium (Ti), molybdenum (Mo), aluminum (Al), or titanium (Ti) and indium tin oxide (ITO), but the exemplary embodiments of the present disclosure are not limited thereto.

According to the present disclosure, some conductive layers having a good reflection efficiency, among a plurality of conductive layers which configures the first electrode CE1 may be configured as an alignment key for alignment of the micro LED (ED) and/or a reflective plate. For example, the second conductive layer CE1b, among the plurality of conductive layers of the first electrode CE1, may include a reflective material. For example, the second conductive layer CE1b may include aluminum (Al), but the exemplary embodiments of the present disclosure are not limited thereto. Therefore, the second conductive layer CE1b may be configured as a reflective plate. Further, the second conductive layer CE1 has a high reflection efficiency to be easily identified during the manufacturing process so that a position of the micro LED (ED) or a transfer position may be aligned based on the second conductive layer CE1b.

For example, in order to the second conductive layer CE1b as a reflective plate, the third conductive layer CE1c and the fourth conductive layer CE1d which cover the second conductive layer CE1b may be partially removed or etched. For example, parts of the third conductive layer CE1c and the fourth conductive layer CE1d disposed on the bank BNK are removed or etched to expose a top surface of the second conductive layer CE1b. For example, a center portion and an edge portion (or a boundary portion) of the third conductive layer CE1c and the fourth conductive layer CE1d in which a solder pattern SDP is disposed remain and the remaining portion excluding the portions may be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 may be suppressed.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which is adhesive to the solder pattern SDP, and has anti-corrosion and acid resistance. However, the exemplary embodiments of the present disclosure are not limited thereto.

The first conductive layer CE1a, the second conductive layer CE1b, the third conductive layer CE1c, and the fourth conductive layer CE1d are sequentially deposited, and then are subject to a photolithographic process and an etching process to be patterned. However, the exemplary embodiments of the present disclosure are not limited thereto.

According to the present disclosure, the signal line TL, the contact electrode CCE, and the pad electrode PE disposed on the same layer as the first electrode CE1 may be configured by multiple layers of conductive materials, but the exemplary embodiments of the present disclosure are not limited thereto. For example, the signal line TL, the contact electrode CCE, and the pad electrode PE may be formed of multiple layers of indium tin oxide (ITO)/titanium (Ti)/aluminum (Al)/titanium (Ti), but the exemplary embodiments of the present disclosure are not limited thereto.

According to the present disclosure, in each of the plurality of sub pixels, a solder pattern SDP may be disposed on the first electrode CE1. The solder pattern SDP bonds the micro LED (ED) to the first electrode CE1 to electrically connect the first electrode CE1 and the micro LED (ED). For example, the first electrode CE1 and the anode electrode 134 of the micro LED (ED) may be electrically connected through eutectic bonding using the solder pattern SDP, but the exemplary embodiments of the present disclosure are not limited thereto. For example, when the solder pattern SDP is configured by indium (In) and the anode electrode 134 of the micro LED (ED) is configured by gold (Au), during the transfer process of the micro LED (ED), heat and pressure are applied to bond the solder pattern SDP and the anode electrode 134. The micro LED (ED) may be bonded to the solder pattern SDP and the first electrode CE1 using the eutectic bonding without a separate adhesive material. For example, the solder pattern SDP may be configured by indium (Id), tin (Sn), or an alloy thereof, but the exemplary embodiments of the present disclosure are not limited thereto. For example, the solder pattern SDP may be a bonding pad or an adhesive pad, but the exemplary embodiments of the present disclosure are not limited thereto.

According to the present disclosure, the passivation layer 116 may be disposed on the plurality of signal lines TL, the plurality of first electrodes CE1, the plurality of contact electrodes CCE, and the third insulating layer 115c. For example, the passivation layer 116 may be disposed in the active arca AA, the first non-active area NA1, and the second non-active area NA2. A part of the passivation layer 116 disposed in the bending area BA may be removed. A part of the passivation layer 116 which covers a plurality of pad electrodes PE in the second non-active area NA2 may be removed. The passivation layer 116 is disposed so as to cover the remaining area excluding the bending area BA, the plurality of pad electrodes PE, and the solder pattern SDP to reduce permeation of moisture or impurities entering the micro LED (ED). For example, the passivation layer 116 may be configured by a single layer or multiple layers of silicon oxide (SiOₓ) or silicon nitride (SiNₓ), but the exemplary embodiments of the present disclosure are not limited thereto. For example, the passivation layer 116 may be a protection layer or an insulating layer, but the exemplary embodiments of the present disclosure are not limited thereto. For example, the passivation layer 116 may include a hole through which the solder pattern SDP is exposed.

In each of the plurality of sub pixels, the micro LED (ED) may be disposed on the solder pattern SDP. A first micro LED 130 may be disposed in the first sub pixel SP1. A second micro LED 140 may be disposed in the second sub pixel SP2. A third micro LED 150 may be disposed in the third sub pixel SP3.

The micro LED (ED) may be formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the exemplary embodiments of the present disclosure are not limited thereto.

Referring to FIG. 11, the first micro LED 130 may include an anode electrode 134, a first semiconductor layer 131, an active layer 132, a second semiconductor layer 133, a cathode electrode 135, and an encapsulation film 136, but the exemplary embodiments of the present disclosure are not limited thereto. For example, the encapsulation film 136 may not be included in the first micro LED 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented by a compound semiconductor, such as a III-V group or a II-VI group and may be doped with an impurity (or dopant). For example, one of the first semiconductor layer 131 and the second semiconductor layer 133 may be an n-type impurity-doped semiconductor layer and the other one may be a p-type impurity-doped semiconductor, but the exemplary embodiments of the present disclosure are not limited thereto. For example, one or more of the first semiconductor layer 131 and the second semiconductor layer 133 may be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the exemplary embodiments of the present disclosure are not limited thereto. For example, the n-type impurity may be silicon (Si), germanium (Ge), selenium (Se), carbon (C), tellurium (Te), or tin (Sn), but the exemplary embodiments of the present disclosure are not limited thereto. For example, the p-type impurity may be magnesium (Mg), zinc (Zn), calcium (Ca), strontium (Sr), barium (Ba), or beryllium (Be), but the exemplary embodiments of the present disclosure are not limited thereto.

For example, each of the first semiconductor layer 131 and the second semiconductor layer 133 may be a nitride semiconductor including an n-type impurity or a nitride semiconductor including a p-type impurity, but the exemplary embodiments of the present disclosure are not limited thereto. For example, the first semiconductor layer 131 may be a nitride semiconductor including a p-type impurity and the second semiconductor layer 133 may be a nitride semiconductor including an n-type impurity, but the exemplary embodiments of the present disclosure are not limited thereto.

The active layer 132 may be disposed between the first semiconductor layer 131 and the second semiconductor layer 133. The active layer 132 is supplied with holes and electrons from the first semiconductor layer 131 and the second semiconductor layer 133 to emit light. For example, the active layer 132 may be configured by one of a single well structure, a multi-well structure, a signal quantum well structure, a multi-quantum well (MQC) structure, a quantum dot structure, and a quantum line structure, but the exemplary embodiments of the present disclosure are not limited thereto. For example, the active layer 132 may be configured by indium gallium nitride (InGaN) or gallium nitride (GaN), but the exemplary embodiments of the present disclosure are not limited thereto.

As another example, the active layer 132 may have a multi quantum well (MQW) structure having a well layer and a barrier layer with a band gap higher than the well layer. For example, in the active layer 132, InGaN may be configured as a well layer and an AlGaN layer may be configured as a barrier layer, but the exemplary embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be configured by a conductive material which may form eutectic bonding with the solder pattern SDP, but the exemplary embodiments of the present disclosure are not limited thereto. For example, the anode electrode 134 may be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the exemplary embodiments of the present disclosure are not limited thereto.

The cathode electrode 135 may be disposed on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be configured by a transparent conductive material to allow light emitted from the micro LED (ED) to be directed to the top of the micro LED (ED), but the exemplary embodiments of the present disclosure are not limited thereto. For example, the cathode electrode 135 may be configured by a material, such as indium tin oxide (ITO), indium zinc oxide (IZO), or indium gallium zinc oxide (IGZO), but the exemplary embodiments of the present disclosure are not limited thereto.

The encapsulation film 136 may be disposed in at least a part of the first semiconductor layer 131, the active layer 132, the second semiconductor layer 133, the anode electrode 134, and the cathode electrode 135. For example, the encapsulation film 136 may enclose at least a part of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a part of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 is exposed from the encapsulation film 136 so that the anode electrode 134 and the solder pattern SDP may be connected. For example, at least a part of the cathode electrode 135 is exposed from the encapsulation film 136 so that the cathode electrode 135 and the second electrode CE2 may be connected. For example, the encapsulation film 136 may be formed of an insulating material, such as silicon nitride (SiNₓ) or silicon oxide (SiOₓ), but the exemplary embodiments of the present disclosure are not limited thereto.

As another example, the encapsulation film 136 may have a structure in which a reflective material is dispersed in a resin layer, but the exemplary embodiments of the present disclosure are not limited thereto. For example, the encapsulation film 136 may be manufactured with reflectors with various structures, but the exemplary embodiments of the present disclosure are not limited thereto. Light emitted from the active layer 132 is upwardly reflected by the encapsulation film 136 so that light extraction efficiency may be improved. For example, the encapsulation film 136 may be a reflective layer, but the exemplary embodiments of the present disclosure are not limited thereto.

According to the present disclosure, it is described that the micro LED (ED) has a vertical structure, but the exemplary embodiments of the present disclosure are not limited thereto. For example, the micro LED (ED) may have a lateral structure or a flip-chip structure.

The first micro LED 130 has been described with reference to FIG. 11 and the second micro LED 140 and the third micro LED 150 may have substantially the same structure as the first micro LED 130. For example, the second micro LED 140 and the third micro LED 150 may be substantially the same as the first semiconductor layer 131, the active layer 132, the second semiconductor layer 133, the anode electrode 134, the cathode electrode 135, and the encapsulation film 136 of the first micro LED 130.

According to the present disclosure, in the active area AA, a first optical layer 117a which encloses the plurality of micro LEDs (ED) may be disposed. For example, the first optical layer 117a may be disposed so as to cover the plurality of micro LEDs (ED) and the bank BNK in the area of the plurality of sub pixels. For example, the first optical layer 117a may cover the bank BNK, a part of the passivation layer 116 and between the plurality of micro LEDs (ED). The first optical layer 117a may be disposed or cover between the plurality of micro LEDs (ED) and between the plurality of banks BNK included in one pixel PX. For example, the first optical layer 117a may extend in the first direction X and may be spaced apart in the second direction Y. For example, the first optical layer 117a may be disposed so as to enclose side portions of the micro LED (ED) and the bank BNK between the passivation layer 116 and the second electrode CE2, but the exemplary embodiments of the present disclosure are not limited thereto. For example, the first optical layer 117a may be a diffusion layer or a side wall diffusion layer, but the exemplary embodiments of the present disclosure are not limited thereto.

The first optical layer 117a may include an organic insulating material in which micro particles are dispersed, but the exemplary embodiments of the present disclosure are not limited thereto. For example, the first optical layer 117a may be configured by siloxane in which micro metal particles, such as titanium dioxide (TiO₂) particles, are dispersed, but the exemplary embodiments of the present disclosure are not limited thereto. Light from the plurality of micro LEDs (ED) is scattered by micro particles dispersed in the first optical layer 117a to be emitted to the outside of the display apparatus 1000. Accordingly, the first optical layer 117a may improve extraction efficiency of light emitted from the plurality of micro LEDs (ED).

For example, the first optical layer 117a may be disposed in each of the plurality of pixels PX or disposed in some pixels PX disposed in the same row together, but the exemplary embodiments of the present disclosure are not limited thereto. For example, the first optical layer 117a may be disposed in each of the plurality of pixels PX or the plurality of pixels PX may share one first optical layer 117a. As another example, each of the plurality of sub pixels may separately include the first optical layer 117a, but the exemplary embodiments of the present disclosure are not limited thereto.

According to the present disclosure, in the active area AA, a second optical layer 117b may be disposed on the passivation layer 116. For example, the second optical layer 117b may be disposed so as to enclose the first optical layer 117a. For example, the second optical layer 117b may be in contact with a side surface of the first optical layer 117a. For example, the second optical layer 117b may be disposed in an area between the plurality of pixels PX. However, the exemplary embodiments of the present disclosure are not limited thereto. For example, the second optical layer 117b may be a diffusion layer, a diffusion window, or a window diffusion layer, but the exemplary embodiments of the present disclosure are not limited thereto.

The second optical layer 117b may be configured by an organic insulating material, but the exemplary embodiments of the present disclosure are not limited thereto. The second optical layer 117b may be configured by the same material as the first optical layer 117a, but the exemplary embodiments of the present disclosure are not limited thereto. For example, the first optical layer 117a may include micro particles, but the second optical layer 117b may not include micro particles.

For example, the second optical layer 117b may be configured by siloxane, but the exemplary embodiments of the present disclosure are not limited thereto.

For example, a thickness of the first optical layer 117a may be smaller than a thickness of the second optical layer 117b, but the exemplary embodiments of the present disclosure are not limited thereto. Accordingly, in the plan view, an area in which the first optical layer 117a is disposed may include a concave portion which is inwardly dented from an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of micro LEDs (ED). For example, the second electrode CE2 may include a transparent conductive oxide, such as indium tin oxide (ITO) or indium zinc oxide (IZO), but the exemplary embodiments of the present disclosure are not limited thereto. For example, the second electrode CE2 may be disposed to be in contact with the cathode electrode 135. For example, the second electrode CE2 may overlap the first optical layer 117a. Further, the second electrode CE2 may extend to an outside of the first optical layer 117a.

The second electrode CE2 may continuously extend in a row direction of the substrate 110. Accordingly, the second electrode may be commonly connected to the plurality of pixels PX disposed in the row direction of the substrate 110. For example, the second electrode CE2 may be commonly connected to the plurality of pixels PX.

According to the present disclosure, the second electrode CE2 may continuously extend on the first optical layer 117a, the second optical layer 117b, and the micro LED (ED). The area in which the first optical layer 117a is disposed may include a concave portion which is inwardly dented from an upper surface of the second optical layer 117b. Accordingly, the first part of the second electrode CE2 disposed on the first optical layer 117a is disposed along the concave portion so that the first part may be disposed to be lower than the second part of the second electrode CE2 disposed on the second optical layer 117b.

The third optical layer 117c may be disposed on the second electrode CE2. The third optical layer 117c may be disposed so as to overlap the plurality of micro LEDs (ED) and the first optical layer 117a. The third optical layer 117c may be disposed above the second electrode CE2 and the plurality of micro LEDs (ED) so that mura which may be generated in some of the plurality of micro LEDs (ED) may be improved. For example, when the plurality of micro LEDs (ED) is transferred onto the substrate 110 of the display apparatus 1000, an area in which the interval between the plurality of micro LEDs (ED) is not uniform may be caused due to a process deviation. When the interval between the plurality of micro LEDs (ED) is not uniform, a light emission area of each of the plurality of micro LEDs (ED) may not be uniformly disposed so that the mura may be visible to a user. Accordingly, the third optical layer 117c which is configured to uniformly diffuse light is configured above the plurality of micro LEDs (ED) so that light emitted from some micro LEDs (ED) which is visible as mura may be reduced. Accordingly, light emitted from the plurality of micro LEDs (ED) is uniformly diffused by the third optical layer 117c to be extracted to the outside of the display apparatus 1000 so that the luminance uniformity of the display apparatus 1000 may be improved.

The third optical layer 117c may be configured by an organic insulating material in which micro particles are dispersed, but the exemplary embodiments of the present disclosure are not limited thereto. For example, the third optical layer 117c may be configured by siloxane in which micro metal particles, such as titanium dioxide (TiO₂) particles, are dispersed, but the exemplary embodiments of the present disclosure are not limited thereto. For example, the third optical layer 117c may be configured by the same material as the first optical layer 117a, but the exemplary embodiments of the present disclosure are not limited thereto. For example, the third optical layer 117c may be a diffusion layer or a upward diffusion layer, but the exemplary embodiments of the present disclosure are not limited thereto.

According to the present disclosure, light from the plurality of micro LEDs (ED) is scattered by micro particles dispersed in the third optical layer 117c to be emitted to the outside of the display apparatus 1000. The third optical layer 117c uniformly mixes light emitted from the plurality of micro LEDs (ED) to further improve the luminance uniformity of the display apparatus 1000. The light extraction efficiency of the display apparatus 1000 may be improved by light scattered from the plurality of micro particles so that the display apparatus 1000 may be driven at a low power.

In the active area AA, a black matrix BM may be disposed on the second electrode CE2, the first optical layer 117a, the second optical layer 117b, and the third optical layer 117c. For example, the contact hole of the second optical layer 117b may be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels may be suppressed.

For example, the black matrix BM may be configured by an opaque material, but the exemplary embodiments of the present disclosure are not limited thereto. For example, the black matrix BM may be configured by an organic insulating material to which black pigment or black dye is added, but the exemplary embodiments of the present disclosure are not limited thereto.

In the active area AA, a cover layer 118 may be disposed on the black matrix BM. The cover layer 118 may protect configurations below the cover layer 118. For example, the cover layer 118 may be configured by an organic insulating material, but the exemplary embodiments of the present disclosure are not limited thereto. For example, the cover layer 118 may be configured by a photo resist, polyimide (PI), or photo acrylic material, but the exemplary embodiments of the present disclosure are not limited thereto. For example, the cover layer 118 may be an over coating layer or an insulating layer, but the exemplary embodiments of the present disclosure are not limited thereto.

A polarization layer 293 may be disposed on the cover layer 118 by means of the first adhesive layer 291. A cover member 200 may be disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the exemplary embodiments of the present disclosure are not limited thereto.

According to the present disclosure, a plurality of pad electrodes PE may be disposed on the third insulating layer 115c in the second non-active area NA2. For example, at least some of the plurality of pad electrodes PE may be exposed from the passivation layer 116. For example, the plurality of pad electrodes PE may be electrically connected to the 2-4-th connection line 122d through a contact hole of the third insulating layer 115c.

The adhesive layer ACF may be disposed on the plurality of pad electrodes PE. The adhesive layer ACF may be an adhesive layer in which conductive balls are dispersed in an insulating material, but the exemplary embodiments of the present disclosure are not limited thereto. When heat or pressure is applied to the adhesive layer ACF, the conductive balls are electrically connected in a portion applied with the heat or pressure to have a conductive property. The adhesive layer ACF is disposed between the plurality of pad electrodes PE and the flexible circuit board (or flexible film) 400 so that the flexible circuit board (or flexible film) 400 may be attached or bonded to the plurality of pad electrodes PE. For example, the adhesive layer ACF may be anisotropic conductive film, but the exemplary embodiments of the present disclosure are not limited thereto.

The flexible circuit board (or flexible film) 400 may be disposed on the adhesive layer ACF. The flexible circuit board (or flexible film) 400 may be electrically connected to the plurality of pad electrodes PE through the adhesive layer ACF. Accordingly, a signal output from the flexible circuit board (or flexible film) 400 and the printed circuit board 500 may be transmitted to the pixel driving circuit PD of the active area AA through the plurality of pad electrodes PE, the 2-4-th connection line 122d, the 2-3nd connection line 122c, the 2-2nd connection line 122b, and the 2-1st connection line 122a.

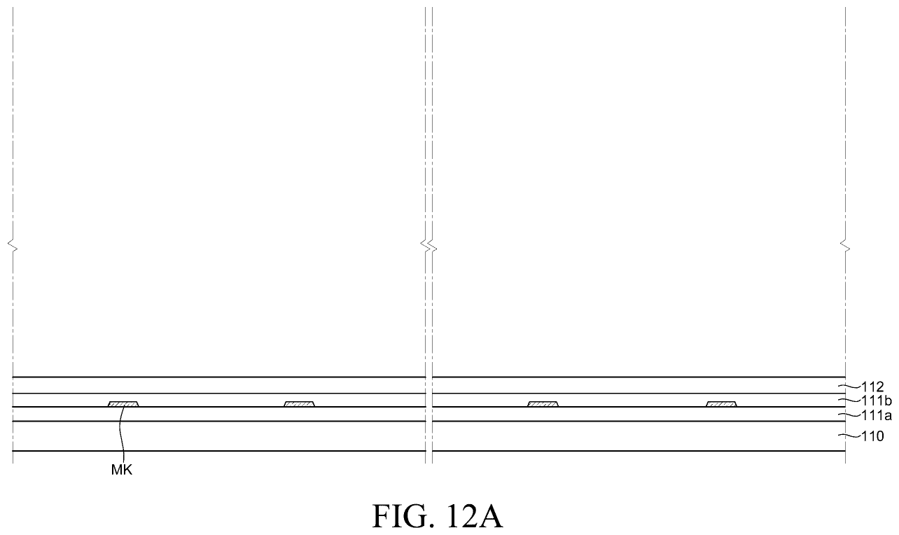

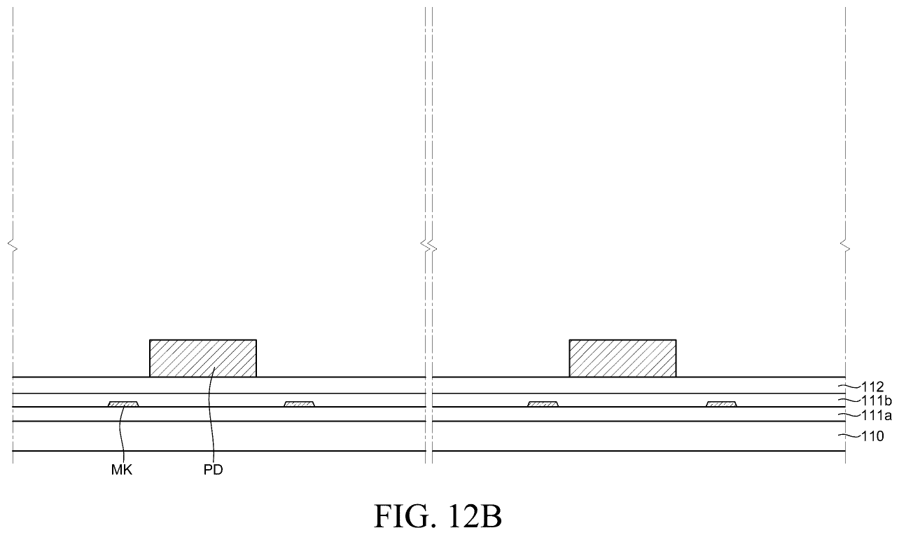

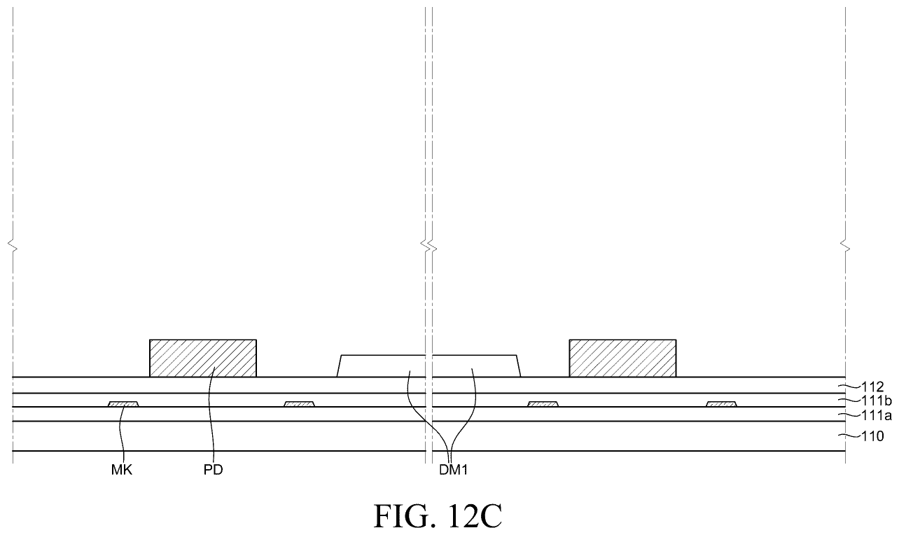

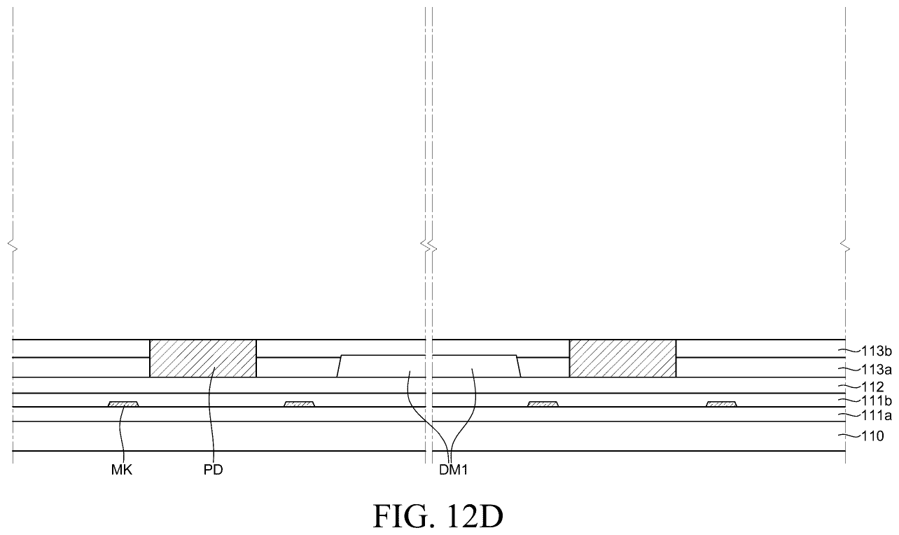

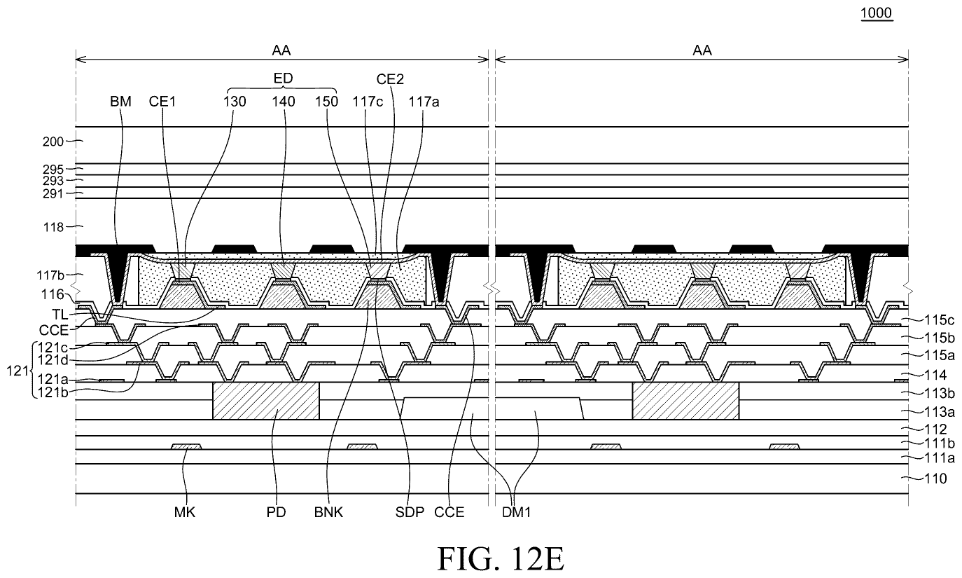

FIGS. 12A to 12E are process diagrams for explaining a manufacturing method of a display apparatus according to an exemplary embodiment of the present disclosure.

Referring to FIG. 12A, a first buffer layer 111a, an alignment key MK, a second buffer layer 111b, and an adhesive layer 112 are sequentially formed on the substrate 110.

Referring to FIG. 12B, a plurality of pixel driving circuits PD is disposed on the adhesive layer 112. The plurality of pixel driving circuits PD may be aligned according to a position of the alignment key MK on the adhesive layer 112.

Referring to FIG. 12C, a dam DM1 is formed on the substrate 110 on which the plurality of pixel driving circuits PD is disposed.

First, an organic layer for forming the dam is disposed with the driving circuit PD therebetween and may be formed to enclose an edge of the driving circuit PD. For example, the organic layer may be formed of photo resist, polyimide (PI), or photo acryl-based material. The organic layer may be formed in a local area. For example, the organic layer may be applied only in a partial area of the top surface of the adhesive layer 112 exposed between the driving circuits PD.

A hardening process is performed after forming the organic layer on the adhesive layer 112. For example, the organic layer may be hardened using heat, UV light, or laser. Therefore, the organic layer is hardened to configure the dam DM1.

Referring to FIG. 12D, a first protection layer 113a and a second protection layer 113b are formed on the adhesive layer 112 on which the plurality of pixel driving circuits PD and the dam DM1 are disposed. The first protection layer 113a and the second protection layer 113b may cover the side surfaces of the plurality of pixel driving circuits PD and the side surface of the dam DM1. Further, the second protection layer 113b may cover the top surface of the dam DM1.

Referring to FIG. 12E, a plurality of connection lines 121, a plurality of signal lines TL, a first electrode CE1, a plurality of micro LEDs (ED), and a second electrode CE2 are formed on the plurality of pixel driving circuits PD and the second protection layer 113b. By doing this, the plurality of pixel driving circuits PD and the plurality of micro LEDs (ED) are electrically connected.

The plurality of pixel driving circuits is disposed to be spaced apart from each other with a predetermined interval. At this time, when the interval between the plurality of pixel driving circuits is increased, the thickness of the protection layer which encloses the plurality of pixel driving circuits may have a deviation between areas. For example, the thickness of the protection layer may be reduced as it is further away from the plurality of pixel driving circuits. Specifically, the protection layer may be formed on the substrate on which the plurality of pixel driving circuits is disposed. At this time, the protection layer may be in an unhardened state. Accordingly, the protection layer may flow to the upper surface of the pixel driving circuit and be hardened on the upper surface of the pixel driving circuit. Accordingly, a height of a portion of a top surface of the protection layer which is in contact with the pixel driving circuit may be larger than a height of a portion of the top surface of the protection layer which is far from the pixel driving circuit. In the meantime, the plurality of connection lines may be disposed on the protection layer. Accordingly, when the top surface of the protection layer is curved, the plurality of connection lines may be formed on the curved top surface of the protection layer. At this time, as the top surface of the protection layer is disposed to be curved, the thickness of the plurality of connection lines may have a thickness deviation between areas. Therefore, when the plurality of connection lines has a thickness deviation, a signal applied to the connection line may have a deviation, which may cause a luminance deviation between pixels.

Accordingly, in the display apparatus 1000 according to the exemplary embodiment of the present disclosure, a dam DM1 is disposed between the plurality of pixel driving circuits PD. The dam DM1 may control a flow of the first protection layer 113a and the second protection layer 113b which enclose the plurality of pixel driving circuits PD. The dam DM1 may uniformize the thicknesses of the first protection layer 113a and the second protection layer 113b. For example, the first protection layer 113a and the second protection layer 113b may be formed on the adhesive layer 112 on which the dam DM1 and the plurality of pixel driving circuits PD are disposed. At this time, the first protection layer 113a and the second protection layer 113b formed on the plurality of pixel driving circuits PD may flow to the outside of the plurality of pixel driving circuits PD. Further, the first protection layer 113a and the second protection layer 113b formed on the dam DM1 may flow to the outside of the dam DM1. However, when the interval between the dam DM1 and the plurality of pixel driving circuits PD is small, top surfaces of the first protection layer 113a and the second protection layer 113b may be uniformly formed. Accordingly, the dam DM1 may minimize the curve of the top surfaces of the first protection layer 113a and the second protection layer 113b.

Further, the dam DM1 may minimize the curve of the top surfaces of the first protection layer 113a and the second protection layer 113b to uniformize the thickness of the plurality of first connection lines 121. For example, when the curve of the top surfaces of the first protection layer 113a and the second protection layer 113b is minimized, the plurality of first connection lines 121 may be formed to have uniform thickness without having a thickness deviation between areas. Accordingly, in the display apparatus 1000 according to the exemplary embodiment of the present disclosure, the deviation which is caused in the signal applied to the plurality of first connection lines 121 may be suppressed so that the luminance deviation between the pixels PX may be suppressed.

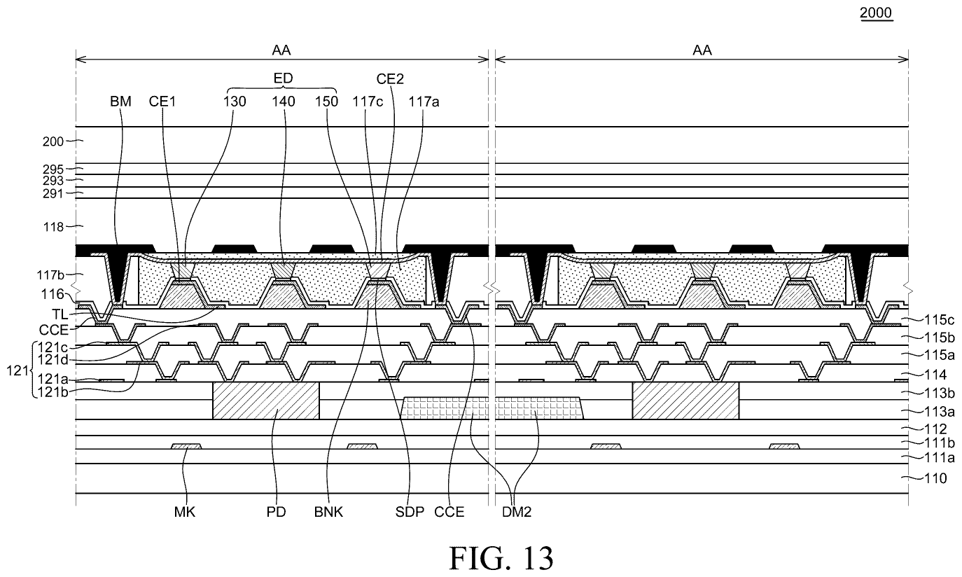

FIG. 13 is a cross-sectional view of a display apparatus according to another exemplary embodiment of the present disclosure. The only difference between a display apparatus of FIG. 13 and the display apparatus 1000 of FIGS. 1 to 11 is a dam DM2, but the other component is substantially the same, so that a redundant description will be omitted.

Referring to FIG. 13, a dam DM2 is disposed on the adhesive layer 112 disposed on the substrate 110. The dam DM2 may be disposed between adjacent pixel driving circuits PD.

Referring to FIG. 13, the dam DM2 may be formed of an inorganic material. For example, the dam DM2 may be formed of an inorganic insulating material. For example, the dam DM2 may be configured by silicon oxide (SiOₓ) or silicon nitride (SiNₓ), but the exemplary embodiments of the present disclosure are not limited thereto. Further, the dam DM2 may be formed of an inorganic conductive material. For example, the dam DM2 may be configured by copper (Cu), aluminum (Al), molybdenum (Mo), nickel (Ni), titanium (Ti), chrome (Cr), or an alloy thereof, but is not limited thereto.

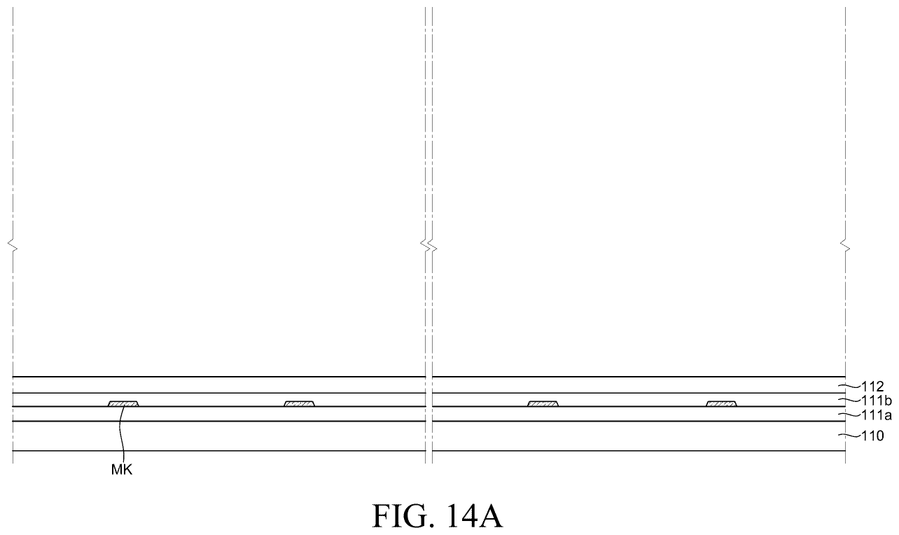

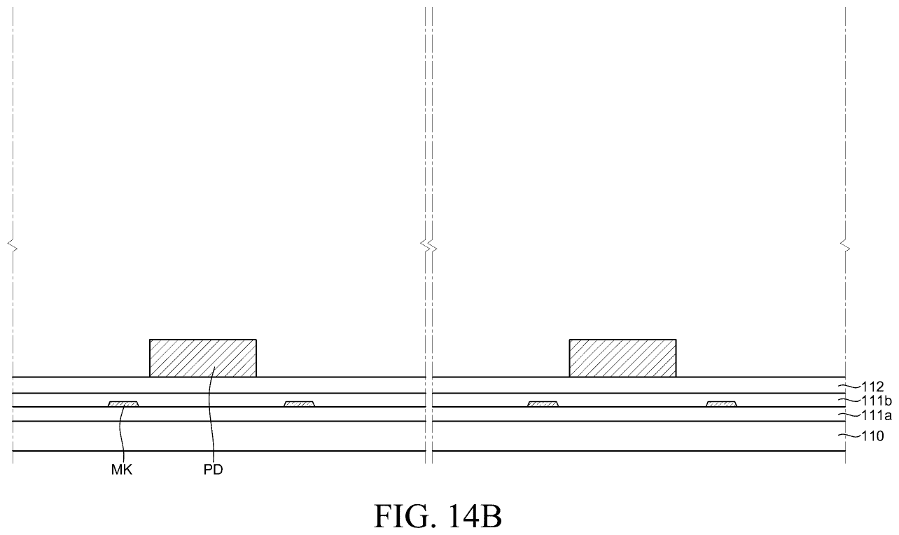

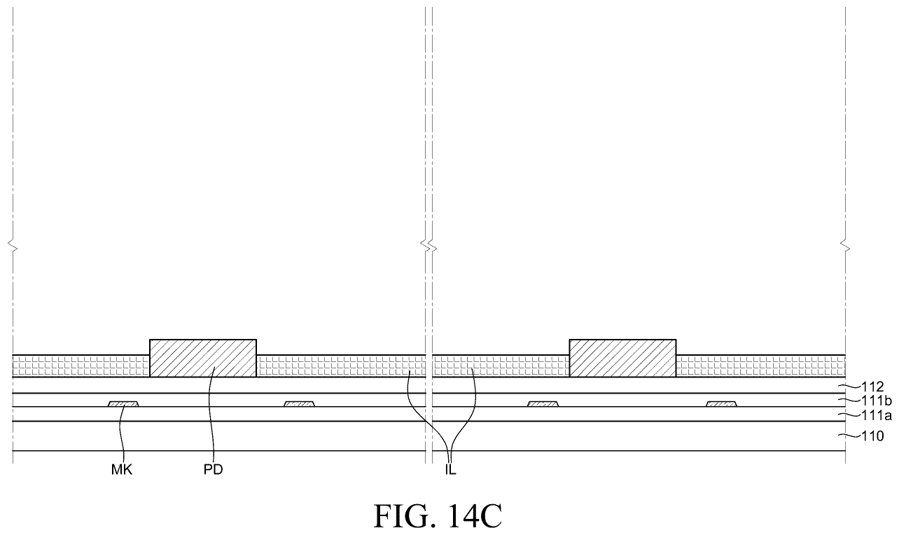

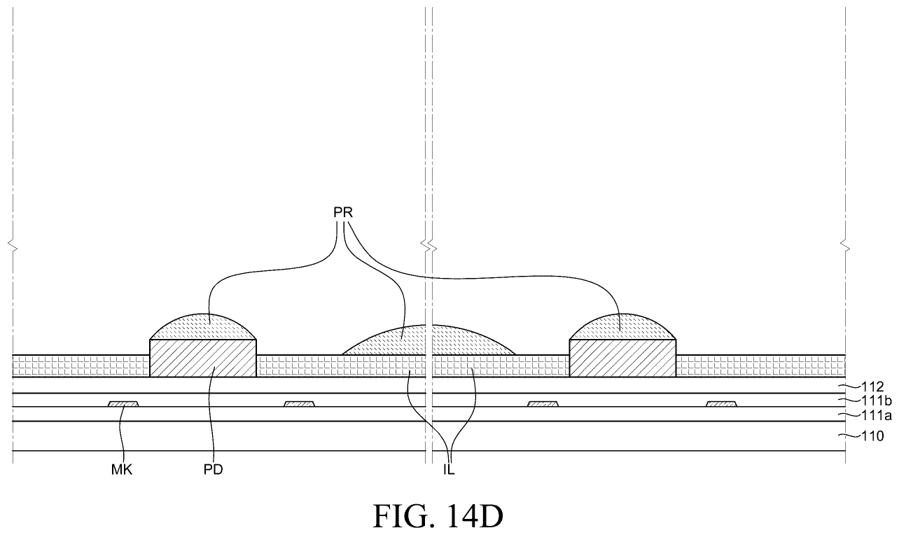

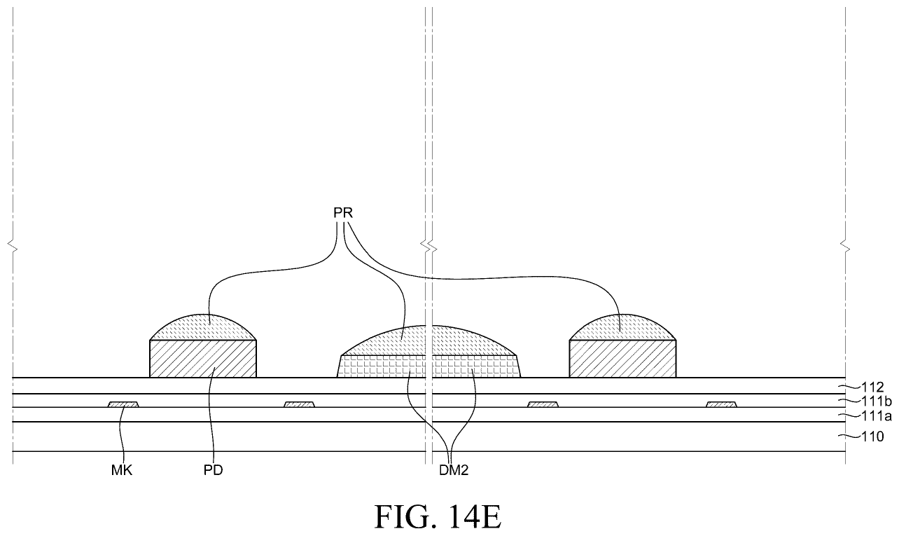

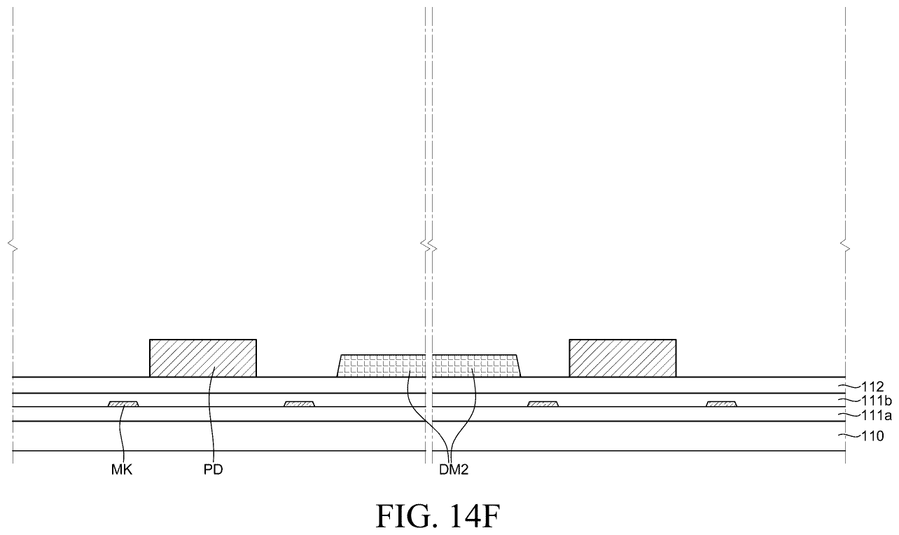

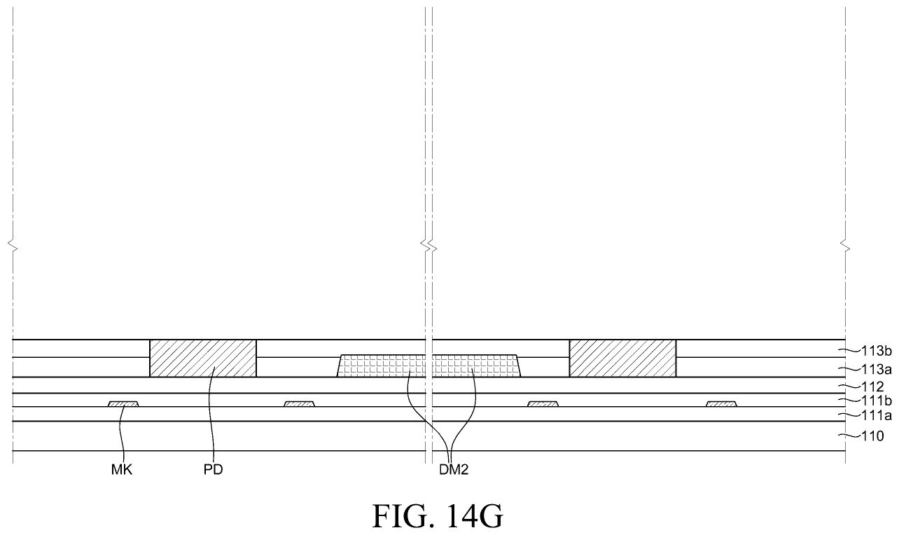

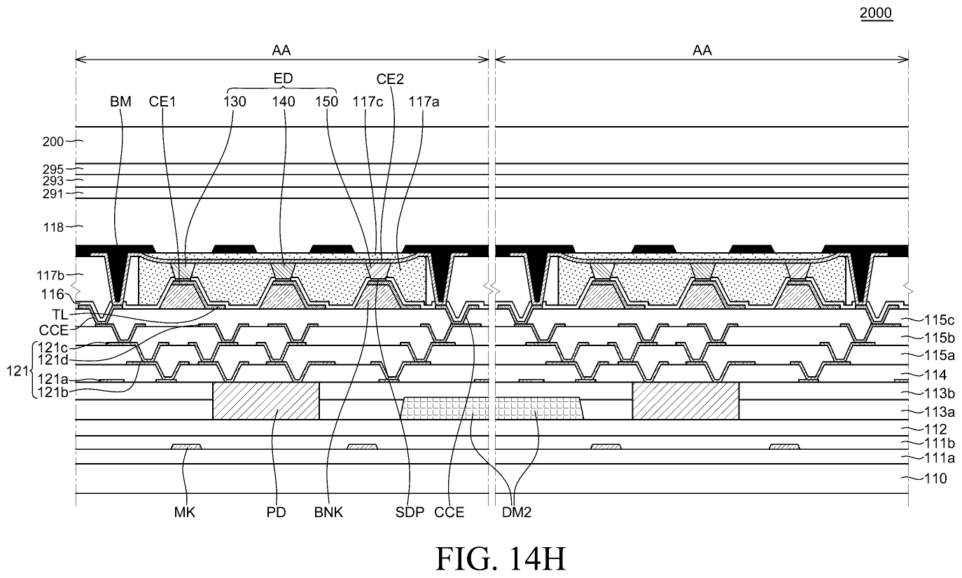

FIGS. 14A to 14H are process diagrams for explaining a manufacturing method of a display apparatus according to other exemplary embodiments of the present disclosure.

Referring to FIG. 14A, a first buffer layer 111a, an alignment key MK, a second buffer layer 111b, and an adhesive layer 112 are sequentially formed on the substrate 110.

Referring to FIG. 14B, a plurality of pixel driving circuits PD is disposed on the adhesive layer 112. The plurality of pixel driving circuits PD may be aligned according to a position of the alignment key MK on the adhesive layer 112.

Referring to FIG. 14C, an inorganic layer IL for forming the dam DM2 on the substrate 110 on which the plurality of pixel driving circuits PD is disposed may be formed on the adhesive layer 112. The inorganic layer IL may be formed in the entire area of the adhesive layer 112 except the plurality of pixel driving circuits PD. For example, the inorganic layer IL may cover a top surface of the adhesive layer 112 exposed between the plurality of pixel driving circuits PD. For example, silicon oxide (SiOₓ) or silicon nitride (SiNₓ) may be formed on the adhesive layer 112 or molybdenum (Mo), aluminum (Al), and molybdenum (Mo) may be formed. The inorganic layer IL may be formed by the deposition process. For example, the inorganic layer IL may be formed on the adhesive layer 112 using a mask having an opening corresponding to an area excluding the plurality of pixel driving circuits PD.

Referring to FIG. 14D, a photo resist PR is formed on the inorganic layer IL and the plurality of pixel driving circuits PD. The photo resist PR may cover all the top surfaces of the plurality of pixel driving circuits PD or cover only a part of the top surface of the inorganic layer IL. For example, the photo resist PR may be formed in an area of the inorganic layer IL excluding an area which encloses edges of the plurality of pixel driving circuits PD.

Referring to FIG. 14E, a part of the inorganic layer IL which encloses the plurality of pixel driving circuits PD is removed to form the dam DM2. For example, if the photo resist PR serves as a mask, the inorganic layer IL may be removed from an area which is not covered by the photo resist PR. For example, the inorganic layer IL may be removed by performing a dry etching process, but is not limited thereto.

Referring to FIG. 14F, a photo resist PR disposed on the plurality of pixel driving circuits PD and the dam DM2 is removed. Accordingly, only the dam DM2 and the plurality of pixel driving circuits PD may remain on the adhesive layer 112.

Referring to FIG. 14G, a first protection layer 113a and a second protection layer 113b are formed on the adhesive layer 112 on which the plurality of pixel driving circuits PD and the dam DM2 are disposed. The first protection layer 113a and the second protection layer 113b may cover the side surfaces of the plurality of pixel driving circuits PD and the side surface of the dam DM2. Further, the second protection layer 113b may cover the top surface of the dam DM2.

Referring to FIG. 14H, a plurality of connection lines 121, a plurality of signal lines TL, a first electrode CE1, a plurality of micro LEDs (ED), and a second electrode CE2 are formed on the plurality of pixel driving circuits PD and the second protection layer 113b. By doing this, the plurality of pixel driving circuits PD and the plurality of micro LEDs (ED) are electrically connected.

In the display apparatus 2000 according to another exemplary embodiment of the present disclosure, the dam DM2 is disposed between the plurality of pixel driving circuits PD. Therefore, the dam DM2 may control the flow of the first protection layer 113a and the second protection layer 113b which enclose the plurality of pixel driving circuits PD and minimize the curve of top surfaces of the first protection layer 113a and the second protection layer 113b.

Further, in the display apparatus 2000 according to another exemplary embodiment of the present disclosure, the dam DM2 may minimize the curve of the top surfaces of the first protection layer 113a and the second protection layer 113b to uniformize the thickness of the plurality of first connection lines 121. Accordingly, the deviation which is caused in the signal applied to the plurality of first connection lines 121 may be suppressed so that the luminance deviation between the pixels PX may be suppressed.

Further, in the display apparatus 2000 according to another exemplary embodiment of the present disclosure, the dam DM2 may be formed of an inorganic material. For example, if the dam is formed of a flowable organic material, it may be difficult to control a shape of the dam. In contrast, in the display apparatus 2000 according to another exemplary embodiment of the present disclosure, the dam DM2 is formed of the inorganic material so that the shape of the dam DM2 may be easily controlled as compared with an example that the dam is formed of an organic material. Further, the dam DM2 may be formed of an inorganic insulating material, such as silicon oxide (SiOₓ) and silicon nitride (SiNₓ). For example, when the dam is formed of an organic material, a moisture permeation issue may be caused in the dam. In contrast, in the display apparatus 2000 according to another exemplary embodiment of the present disclosure, the dam DM2 is formed of the inorganic insulating material so that it is effective to block the moisture as compared with an example that the dam is formed of an organic material.

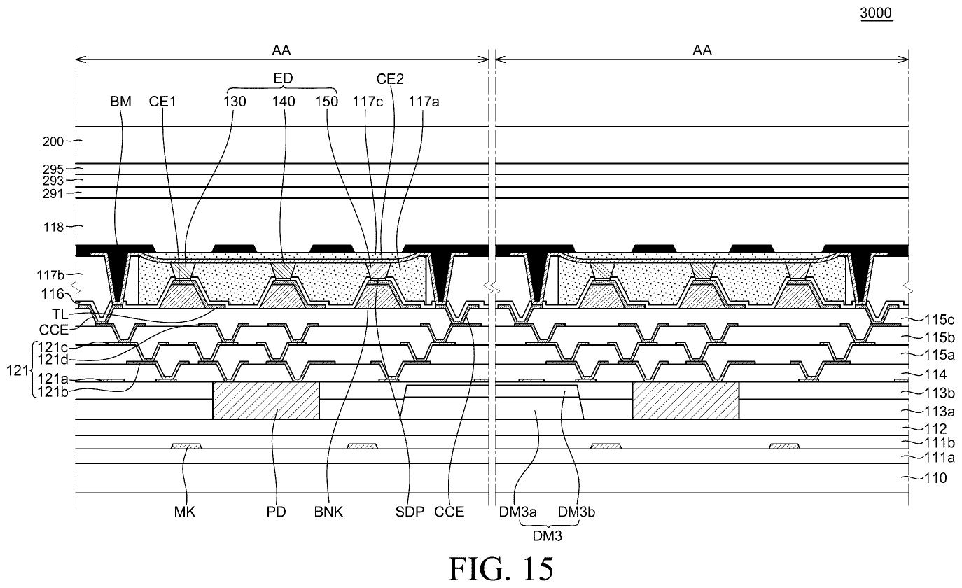

FIG. 15 is a cross-sectional view of a display apparatus according to still another exemplary embodiment of the present disclosure. The only difference between a display apparatus 3000 of FIG. 15 and the display apparatus 1000 of FIGS. 1 to 11 is a dam DM3, but the other component is substantially the same, so that a redundant description will be omitted.

Referring to FIG. 15, a dam DM3 is disposed on the adhesive layer 112 disposed on the substrate 110. The dam DM3 may be disposed between adjacent pixel driving circuits PD.

The dam DM3 may be formed by a plurality of layers. For example, the dam DM3 may include a first layer DM3a and a second layer DM3b disposed on the first layer DM3a.

The first layer DM3a and the second layer DM3b may be formed of an organic material. For example, the dam DM3 may be formed of photo resist, polyimide (PI), or photo acryl-based material. The first layer DM3a and the second layer DM3b may be formed of an inorganic material. For example, the dam DM3 may be formed of an inorganic insulating material, such as silicon oxide (SiOₓ) and silicon nitride (SiNₓ) or may be formed of an inorganic conductive material, such as copper (Cu), aluminum (Al), molybdenum (Mo), nickel (Ni), titanium (Ti), chrome (Cr), or an alloy thereof.

In the meantime, the first layer DM3a and the second layer DM3b may be formed of the same material or formed of different materials. For example, the first layer DM3a may be formed of an organic material and the second layer DM3b may be formed of an inorganic material. Further, the first layer DM3a may be formed of an inorganic material and the second layer DM3b may be formed of an organic material.

In the display apparatus 3000 according to still another exemplary embodiment of the present disclosure, the dam DM3 is disposed between the plurality of pixel driving circuits PD. Therefore, the dam DM3 may control the flow of the first protection layer 113a and the second protection layer 113b which enclose the plurality of pixel driving circuits PD and minimize the curve of top surfaces of the first protection layer 113a and the second protection layer 113b.

Further, in the display apparatus 3000 according to still another exemplary embodiment of the present disclosure, the dam DM3 may minimize the curve of the top surfaces of the first protection layer 113a and the second protection layer 113b to uniformize the thickness of the plurality of first connection lines 121. Accordingly, the deviation which is caused in the signal applied to the plurality of first connection lines 121 may be suppressed so that the luminance deviation between the pixels PX may be suppressed.

Further, in the display apparatus 3000 according to still another exemplary embodiment of the present disclosure, the dam DM3 may be configured by a plurality of layers. For example, the dam DM3 may include a first layer DM3a and a second layer DM3b disposed on the first layer DM3a. Accordingly, in the display apparatus 3000 according to still another exemplary embodiment of the present disclosure, the thickness of the dam DM3 may be effectively controlled. For example, if the dam is configured by a single layer formed of an inorganic material, a difference between a thickness of the dam and the thickness of the plurality of pixel driving circuits may be increased. Accordingly, the effect of the dam which controls the flow of the first protection layer and the second protection layer may be insignificant and it may be difficult to improve the flatness of the top surface of the second protection layer. Accordingly, in the display apparatus 3000 according to still another exemplary embodiment of the present disclosure, the dam DM3 is configured by a plurality of layers to control the thickness of the dam DM3. For example, the dam DM3 may have a thickness corresponding to a thickness of the plurality of pixel driving circuits PD. Therefore, the dam DM3 may effectively control the flow of the first protection layer 113a and the second protection layer 113b which is caused in an area adjacent to the plurality of pixel driving circuits PD and minimize the curve of the top surfaces of the first protection layer 113a and the second protection layer 113b.

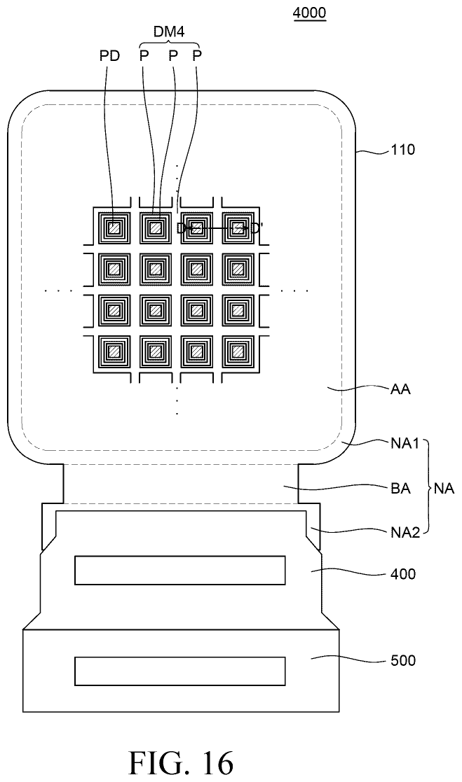

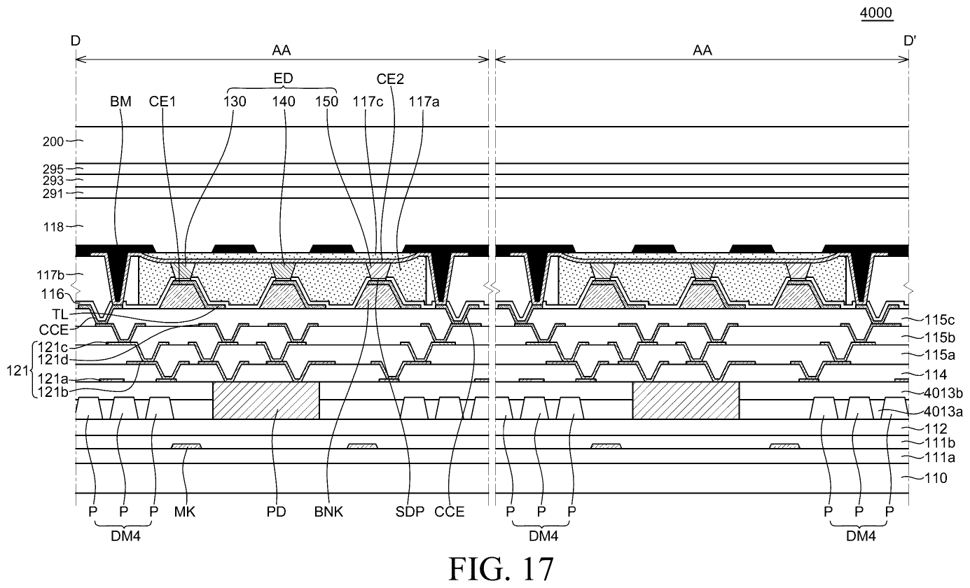

FIG. 16 is a plan view of a display apparatus according to still another exemplary embodiment of the present disclosure. FIG. 17 is a cross-sectional view taken along D-D′ of FIG. 16. FIG. 17 is a cross-sectional view of a display apparatus according to still another exemplary embodiment of the present disclosure. The only difference between a display apparatus 4000 of FIGS. 16 and 17 and the display apparatus 1000 of FIGS. 1 to 11 is a dam DM4, a first protection layer 4013a, and a second protection layer 4013b, but the other component is substantially the same, so that a redundant description will be omitted.

Referring to FIGS. 16 and 17, a dam DM4 may be disposed between adjacent pixel driving circuits PD.

Referring to FIG. 16, the dam DM4 may include a plurality of patterns P which is spaced apart from each other with different intervals from centers of the plurality of pixel driving circuits PD. Each of the plurality of patterns P may be disposed so as to enclose the pixel driving circuit PD. For example, the plurality of patterns P may be a closed curve which encloses the pixel driving circuit PD. That is, the plurality of patterns P may be a structure including a plurality of openings which is formed to overlap the pixel driving circuits PD.

The dam DM4 may be formed of an organic material.

A first protection layer 4013a and a second protection layer 4013b may be disposed on the adhesive layer 112, the dam DM4, and the pixel driving circuit PD. The first protection layer 4013a and the second protection layer 4013b may fill a space between the plurality of patterns P. For example, the first protection layer 4013a and the second protection layer 4013b may cover side surfaces of the plurality of patterns P and the second protection layer 4013b may cover top surfaces of the plurality of patterns P.

In the display apparatus 4000 according to still another exemplary embodiment of the present disclosure, the dam DM4 is disposed between the plurality of pixel driving circuits PD. Therefore, the dam DM4 may control the flow of the first protection layer 4013a and the second protection layer 4013b which enclose the plurality of pixel driving circuits PD and minimize the curve of top surfaces of the first protection layer 4013a and the second protection layer 4013b.

Further, in the display apparatus 4000 according to still another exemplary embodiment of the present disclosure, the dam DM4 may minimize the curve of the top surfaces of the first protection layer 4013a and the second protection layer 4013b to uniformize the thickness of the plurality of first connection lines 121. Accordingly, the deviation which is caused in the signal applied to the plurality of first connection lines 121 may be suppressed so that the luminance deviation between the pixels PX may be suppressed.

Further, in the display apparatus 4000 according to still another exemplary embodiment of the present disclosure, the dam DM4 may include a plurality of patterns P which is spaced apart from each other with different intervals from centers of the plurality of pixel driving circuits PD. Therefore, the first protection layer 4013a and the second protection layer 4013b fill the space between the plurality of patterns P and the flow of the first protection layer 4013a and the second protection layer 4013b disposed on the dam DM4 may be easily controlled. Accordingly, the deviation which is caused in the signal applied to the plurality of first connection lines 121 may be suppressed so that the luminance deviation between the pixels PX may be suppressed.

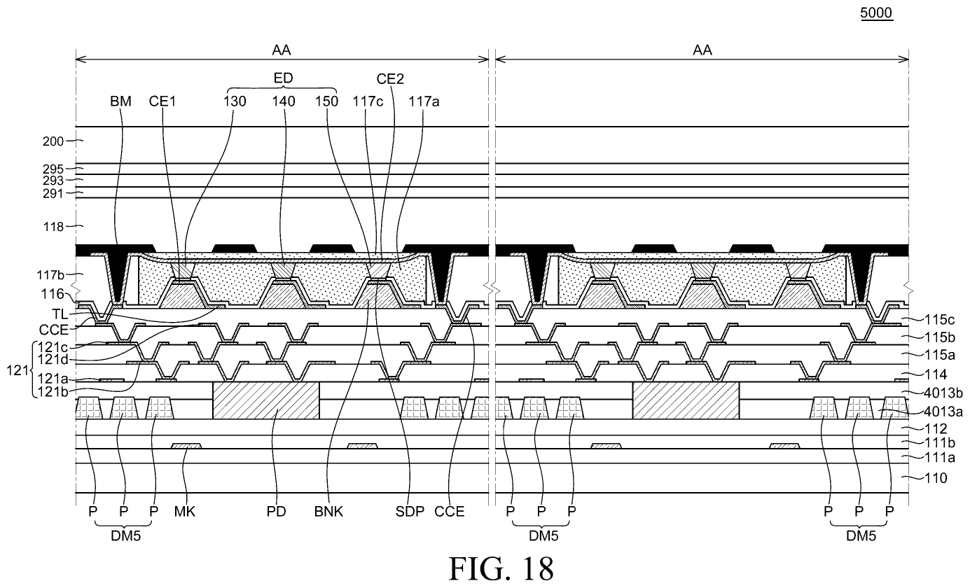

FIG. 18 is a cross-sectional view of a display apparatus according to still another exemplary embodiment of the present disclosure. FIG. 18 is a cross-sectional view of a display apparatus according to still another exemplary embodiment of the present disclosure. The only difference between a display apparatus 5000 of FIG. 18 and the display apparatus 4000 of FIGS. 16 and 17 is a dam DM5, but the other component is substantially the same, so that a redundant description will be omitted.

Referring to FIG. 18, a dam DM5 is disposed on the adhesive layer 112 disposed on the substrate 110. The dam DM5 may include a plurality of patterns P which is spaced apart from each other with different intervals from centers of the adjacent pixel driving circuits PD.

The dam DM5 may be formed of an inorganic material. For example, the dam DM5 may be formed of an inorganic insulating material. For example, the dam DM5 may be configured by silicon oxide (SiOₓ) or silicon nitride (SiNₓ), but the exemplary embodiments of the present disclosure are not limited thereto. Further, the dam DM5 may be formed of an inorganic conductive material. For example, the dam DM5 may be configured by copper (Cu), aluminum (Al), molybdenum (Mo), nickel (Ni), titanium (Ti), chrome (Cr), or an alloy thereof, but is not limited thereto.

In the display apparatus 5000 according to still another exemplary embodiment of the present disclosure, the dam DM5 is disposed between the plurality of pixel driving circuits PD. Therefore, the dam DM5 may control the flow of the first protection layer 4013a and the second protection layer 4013b which enclose the plurality of pixel driving circuits PD and minimize the curve of top surfaces of the first protection layer 4013a and the second protection layer 4013b.

Further, in the display apparatus 5000 according to still another exemplary embodiment of the present disclosure, the dam DM5 may minimize the curve of the top surfaces of the first protection layer 4013a and the second protection layer 4013b to uniformize the thickness of the plurality of first connection lines 121. Accordingly, the deviation which is caused in the signal applied to the plurality of first connection lines 121 may be suppressed so that the luminance deviation between the pixels PX may be suppressed.

Further, in the display apparatus 5000 according to still another exemplary embodiment of the present disclosure, the dam DM5 may include a plurality of patterns P which is spaced apart from each other with different intervals from centers of the plurality of pixel driving circuits PD. Accordingly, in the display apparatus 5000 according to still another exemplary embodiment of the present disclosure, the curve of the top surfaces of the first protection layer 4013a and the second protection layer 4013b between the plurality of pixel driving circuits PD may be minimized.

Further, in the display apparatus 5000 according to still another exemplary embodiment of the present disclosure, the dam DM5 may be formed of an inorganic material. For example, the dam DM5 may be formed of an inorganic insulating material. Accordingly, the dam DM5 may be effective to block the moisture as compared with an example that the dam is formed of an organic material. Further, the dam DM5 may be formed of an inorganic conductive material. Accordingly, in the display apparatus 5000 according to another exemplary embodiment of the present disclosure, the dam DM5 is formed of the inorganic conductive material so that the shape of the dam DM5 may be easily controlled as compared with an example that the dam is formed of an organic material.

Further, in the display apparatus 5000 according to still another exemplary embodiment of the present disclosure, the dam DM5 may be formed of an inorganic material. Therefore, when the dam DM5 is formed of an inorganic material, the plurality of patterns P having a fine pattern may be easily formed as compared with an example that the dam is formed of an organic material. Accordingly, in the display apparatus 5000 according to still another exemplary embodiment of the present disclosure, the dam DM5 including a plurality of patterns P may be easily formed. Further, the curve of the top surfaces of the first protection layer 4013a and the second protection layer 4013b between the plurality of pixel driving circuits PD may be minimized.

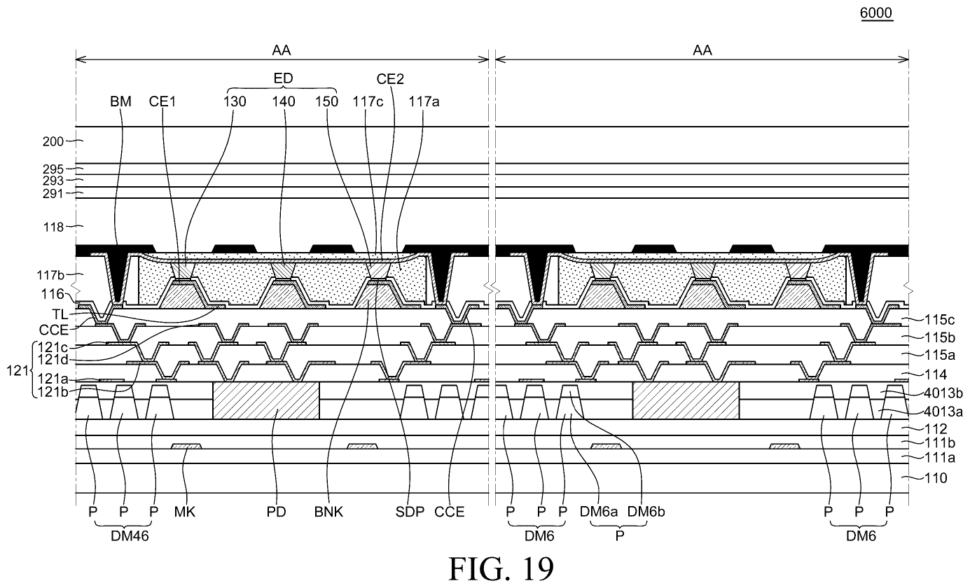

FIG. 19 is a cross-sectional view of a display apparatus according to still another exemplary embodiment of the present disclosure. The only difference between a display apparatus 6000 of FIG. 19 and the display apparatus 4000 of FIGS. 16 and 17 is a dam DM6, but the other component is substantially the same, so that a redundant description will be omitted.

Referring to FIG. 19, a dam DM6 is disposed on the adhesive layer 112 disposed on the substrate 110. The dam DM6 may include a plurality of patterns P which is spaced apart from each other with different intervals from centers of the adjacent pixel driving circuits PD.

Each of the plurality of patterns P may be formed by a plurality of layers. For example, the plurality of patterns P may include a first layer DM6a and a second layer DM6b disposed on the first layer DM6a.

The first layer DM6a and the second layer DM6b may be formed of an organic material. The first layer DM6a and the second layer DM6b may be formed of an inorganic material. In the meantime, the first layer DM6a and the second layer DM6b may be formed of the same material or formed of different materials. For example, the first layer DM6a may be formed of an organic material and the second layer DM6b may be formed of an inorganic material. Further, the first layer DM6a may be formed of an inorganic material and the second layer DM6b may be formed of an organic material.

In the display apparatus 6000 according to still another exemplary embodiment of the present disclosure, the dam DM6 is disposed between the plurality of pixel driving circuits PD. Therefore, the dam DM6 may control the flow of the first protection layer 4013a and the second protection layer 4013b which enclose the plurality of pixel driving circuits PD and minimize the curve of top surfaces of the first protection layer 4013a and the second protection layer 4013b.

Further, in the display apparatus 6000 according to still another exemplary embodiment of the present disclosure, the dam DM6 may minimize the curve of the top surfaces of the first protection layer 4013a and the second protection layer 4013b to uniformize the thickness of the plurality of first connection lines 121. Accordingly, the deviation which is caused in the signal applied to the plurality of first connection lines 121 may be suppressed so that the luminance deviation between the pixels PX may be suppressed.

Further, in the display apparatus 6000 according to still another exemplary embodiment of the present disclosure, the dam DM6 may include a plurality of patterns P which is spaced apart from each other with different intervals from centers of the plurality of pixel driving circuits PD. Accordingly, in the display apparatus 6000 according to still another exemplary embodiment of the present disclosure, the curve of the top surfaces of the first protection layer 4013a and the second protection layer 4013b between the plurality of pixel driving circuits PD may be minimized.

Further, in the display apparatus 6000 according to still another exemplary embodiment of the present disclosure, each of the plurality of patterns P may be configured by a plurality of layers. For example, cach of the plurality of patterns P may include a first layer DM6a and a second layer DM6b disposed on the first layer DM6a. Accordingly, in the display apparatus 6000 according to still another exemplary embodiment of the present disclosure, a thickness of the thickness of the dam DM6 is effectively controlled to minimize the curve of the top surfaces of the first protection layer 4013a and the second protection layer 4013b.

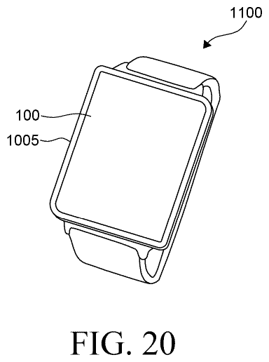

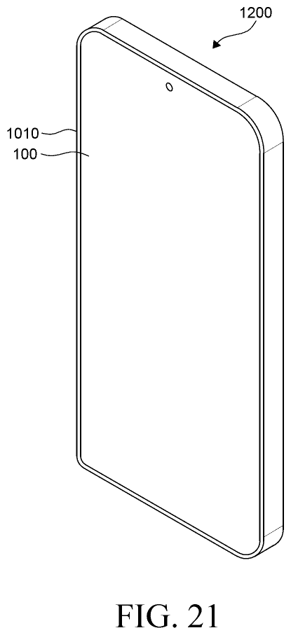

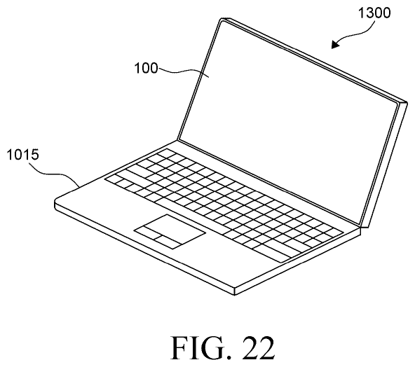

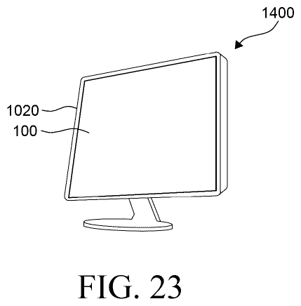

FIGS. 20 to 23 are views illustrating devices to which a display apparatus according to exemplary embodiments of the present disclosure is applied.

Referring to FIGS. 20 to 23, the display apparatus 1000 according to the exemplary embodiments of the present disclosure may be included in various devices or electronic devices. For example, referring to FIGS. 20 to 23, various electronic devices may include a wearable device 1100, a mobile device 1200, a laptop 1300, and a monitor or TV 1400, but the exemplary embodiments of the present disclosure are not limited thereto.

Each of the wearable device 1100, the mobile device 1200, the laptop 1300, and a monitor or TV 1400 may include case units 1005, 1010, 1015, and 1020 and display panel 100 and the display apparatus 1000 according to the exemplary embodiments of the present disclosure which have been described in FIGS. 1 to 17, respectively.

For example, the display apparatus 1000 according to the exemplary embodiment of the present disclosure may be applicable to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic note, an electronic book, a portable multimedia player (PMP), a personal digital assistant (PDA), an MP3 player, a mobile medical apparatus, a desktop PC, a laptop PC, a netbook computer, a workstation, a navigation, a display apparatus for a vehicle, a theatrical display apparatus, a television, a wallpaper device, a signage device, a game device, a laptop, a monitor, a camera, a camcorder, and a consumer electronics device.

The exemplary embodiments of the present disclosure can also be described as follows:
According to an aspect of the present disclosure, there is provided a display apparatus. The display apparatus comprises a substrate, a plurality of pixel driving circuits disposed on the substrate, a plurality of insulating layers disposed on the plurality of pixel driving circuits, a plurality of banks disposed on the plurality of insulating layers, a plurality of micro LEDs which is disposed on the plurality of banks and is electrically connected to each of the plurality of pixel driving circuits, and a dam which is disposed on the same layer as the plurality of pixel driving circuits and is disposed between adjacent pixel driving circuits, among the plurality of pixel driving circuits.

The display apparatus may further comprise a plurality of first connection lines which connects the plurality of micro LEDs and the plurality of pixel driving circuits, wherein the dam may be disposed so as to overlap some of the plurality of first connection lines below the plurality of first connection lines.

The dam may surrounds each of the plurality of pixel driving circuits.

The display apparatus may further comprise an adhesive layer disposed on the substrate, wherein the dam and the plurality of pixel driving circuits may be in contact with a top surface of the adhesive layer.

The display apparatus may further comprise a protection layer which disposed on the substrate and covers the plurality of pixel driving circuits, wherein the protection layer may fill a space between the plurality of pixel driving circuits and the dam.

The protection layer may cover at least a part of a top surface of the dam and a side surface thereof.

The protection layer may cover side surfaces of the plurality of pixel driving circuits.

The dam may include a plurality of patterns which is spaced apart from centers of the plurality of pixel driving circuits with different intervals.

The protection layer may fill a space between adjacent patterns, among the plurality of patterns.

The dam is formed of an organic material.

The dam is formed of an inorganic material.

The dam is configured by a plurality of layers.

The dam may include a plurality of patterns which is spaced apart from centers of the plurality of pixel driving circuits with different intervals.

The dam may be disposed so as to overlap at least one micro LEDs, among the plurality of micro LEDs.

The display apparatus may further comprise a plurality of alignment keys disposed between the substrate and the plurality of pixel driving circuits, wherein the dam may be disposed between the plurality of alignment keys.

Each of the plurality of micro LEDs may include an anode electrode, a first semiconductor layer disposed on the anode electrode, an active layer disposed on the first semiconductor layer, a second semiconductor layer disposed on the active layer, and a cathode electrode disposed on the second semiconductor layer.

The display apparatus may further comprise a first electrode which is disposed below the plurality of micro LEDs to electrically connect the plurality of pixel driving circuits and the anode electrodes of the plurality of micro LEDs; and a solder pattern which is disposed between the first electrode and the anode electrode, wherein the first electrode and the anode electrode may be electrically connected by eutectic bonding using the solder pattern.

According to another aspect of the present disclosure, there is provided a display apparatus. The display apparatus comprises a substrate including an active area including a plurality of pixels and a non-active area, a structure which is disposed on the substrate and includes a plurality of openings, a plurality of pixel driving circuits which is disposed on the substrate and is disposed in cach of the plurality of openings, a plurality of insulating layers disposed on the substrate, a plurality of banks disposed in the plurality of pixels on the plurality of insulating layers, a plurality of micro LEDs which is disposed on the plurality of banks and is electrically connected to each of the plurality of pixel driving circuits, and a plurality of first connection lines which is disposed so as to overlap the structure and connects the plurality of micro LEDs and the plurality of pixel driving circuits.

The structure may be disposed so as to overlap at least one pixels, among the plurality of pixels.

The display apparatus may further comprise a plurality of alignment keys disposed on the substrate, wherein the plurality of alignment keys may be disposed in the plurality of openings.

Each of the plurality of micro LEDs may include an anode electrode, a first semiconductor layer disposed on the anode electrode, an active layer disposed on the first semiconductor layer, a second semiconductor layer disposed on the active layer, and a cathode electrode disposed on the second semiconductor layer and has a vertical type structure.

The display apparatus may further comprise a first electrode disposed below the plurality of micro LEDs, and a solder pattern which is disposed between the first electrode and the anode electrode, wherein the anode electrode may be bonded to the first electrode by eutectic bonding using the solder pattern.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate;
a plurality of pixel driving circuits on the substrate;
a plurality of insulating layers on the plurality of pixel driving circuits;
a plurality of banks on the plurality of insulating layers;
a plurality of micro LEDs on the plurality of banks and electrically connected to each of the plurality of pixel driving circuits; and
a dam on a same layer as the plurality of pixel driving circuits and disposed between adjacent pixel driving circuits, among the plurality of pixel driving circuits.

2. The display apparatus according to claim 1, further comprising:
a plurality of first connection lines connected between the plurality of micro LEDs and the plurality of pixel driving circuits,
wherein the dam is disposed so as to overlap some of the plurality of first connection lines below the plurality of first connection lines.

3. The display apparatus according to claim 1, wherein the dam surrounds each of the plurality of pixel driving circuits.

4. The display apparatus according to claim 1, further comprising:
an adhesive layer on the substrate,
wherein the dam and the plurality of pixel driving circuits are in contact with a top surface of the adhesive layer.

5. The display apparatus according to claim 1, further comprising:
a protection layer on the substrate and covering the plurality of pixel driving circuits, wherein the protection layer at least partially fills a space between the plurality of pixel driving circuits and the dam.

6. The display apparatus according to claim 5, wherein the protection layer covers at least a part of a top surface of the dam and a side surface thereof.

7. The display apparatus according to claim 6, wherein the protection layer covers side surfaces of the plurality of pixel driving circuits.

8. The display apparatus according to claim 6,
wherein the dam includes a plurality of patterns which is spaced apart from centers of the plurality of pixel driving circuits with different intervals.

9. The display apparatus according to claim 8, wherein the protection layer at least partially fills a space between adjacent patterns, among the plurality of patterns.

10. The display apparatus according to claim 1, wherein the dam is formed of either an organic material or an inorganic material.

11. The display apparatus according to claim 1, wherein the dam is configured by a plurality of layers.

12. The display apparatus according to claim 11,
wherein the dam includes a plurality of patterns which is spaced apart from centers of the plurality of pixel driving circuits with different intervals.

13. The display apparatus according to claim 1, wherein the dam is disposed so as to overlap at least one micro LEDs, among the plurality of micro LEDs.

14. The display apparatus according to claim 1, further comprising:
a plurality of alignment keys disposed between the substrate and the plurality of pixel driving circuits,
wherein the dam is disposed between the plurality of alignment keys.

15. The display apparatus according to claim 1, wherein each of the plurality of micro LEDs includes:
an anode electrode;
a first semiconductor layer on the anode electrode;
an active layer on the first semiconductor layer;
a second semiconductor layer on the active layer; and
a cathode electrode on the second semiconductor layer.

16. The display apparatus according to claim 15, further comprising:
a first electrode which is disposed below the plurality of micro LEDs to electrically connect the plurality of pixel driving circuits and the anode electrodes of the plurality of micro LEDs; and
a solder pattern which is disposed between the first electrode and the anode electrode,
wherein the first electrode and the anode electrode are electrically connected by eutectic bonding using the solder pattern.

17. A display apparatus, comprising:
a substrate including an active area including a plurality of pixels and a non-active area;
a structure on the substrate and including a plurality of openings;
a plurality of pixel driving circuits on the substrate and disposed in each of the plurality of openings;
a plurality of insulating layers on the substrate;
a plurality of banks disposed in the plurality of pixels on the plurality of insulating layers;
a plurality of micro LEDs on the plurality of banks and electrically connected to each of the plurality of pixel driving circuits; and
a plurality of first connection lines which is disposed so as to overlap the structure and connects the plurality of micro LEDs and the plurality of pixel driving circuits.

18. The display apparatus according to claim 17, wherein the structure is disposed so as to overlap at least one pixels, among the plurality of pixels.

19. The display apparatus according to claim 18, further comprising:
a plurality of alignment keys on the substrate,
wherein the plurality of alignment keys is disposed in the plurality of openings.

20. The display apparatus according to claim 17, wherein each of the plurality of micro LEDs includes an anode electrode, a first semiconductor layer on the anode electrode, an active layer on the first semiconductor layer, a second semiconductor layer on the active layer, and a cathode electrode on the second semiconductor layer and has a vertical type structure.

21. The display apparatus according to claim 20, further comprising:
a first electrode disposed below the plurality of micro LEDs; and
a solder pattern which is disposed between the first electrode and the anode electrode,
wherein the anode electrode is bonded to the first electrode by eutectic bonding using the solder pattern.

22. A display apparatus, comprising:
a substrate;
a plurality of pixel driving circuits on the substrate;
a protection layer on the substrate and covers the plurality of pixel driving circuits;
a plurality of banks on the protection layer;
a plurality of micro LEDs on the plurality of banks;
a plurality of connection lines on the protection layer and electrically connected to the plurality of pixel driving circuits; and
a dam between adjacent pixel driving circuits, among the plurality of pixel driving circuits.
